(19) United States
(12) Patent Application Publication
(10) Pub. No.: US 2009/0087561 A1
(43) Pub. Date: Apr. 2, 2009

(54) METAL AND METALLOID SILYLAMIDES, KETIMATES, TETRAALKYLGUANIDINATES AND DIANIONIC GUANIDINATES USEFUL FOR CVD/ALD OF THIN FILMS

(75) Inventors: Tianniu CHEN, Rocky Hill, CT (US); Chongying Xu, New Milford, CT (US); William Hunks, Waterbury, CT (US); Jeffrey F. Roeder, Brookfield, CT (US); Thomas H. Baum, New Fairfield, CT (US)

Correspondence Address: INTELLECTUAL PROPERTY / TECHNOLOGY LAW, PO BOX 14329, RESEARCH TRIANGLE PARK, NC, 27709, US

(73) Assignee: Advanced Technology Materials, Inc., Danbury, CT (US)

(21) Appl. No.: 12/239,808

(22) Filed: Sep. 28, 2008

Related U.S. Application Data
(60) Provisional application No. 60/976,408, filed on Sep. 28, 2007.
(60) Provisional application No. 61/050,181, filed on May 2, 2008.

(51) Int. Cl. C07F 7/30; C23C 16/18

(52) U.S. Cl. 427/252; 556/409; 556/12

(57) ABSTRACT

Metal and metalloid precursors useful for forming metal-containing films on substrates, including amide precursors, tetraalkylguanidinate precursors, ketimate and dianionic guanidinate precursors. The precursors of the invention are readily formed and conveniently used to carry out chemical vapor deposition or atomic layer deposition at low temperature, e.g., at temperature below 400° C.

### CROSS-REFERENCE TO RELATED APPLICATIONS

The benefit of priority of U.S. Provisional Patent Application No. 60/976,408 filed Sep. 28, 2007 and U.S. Provisional Patent Application No. 61/050,181 filed May 2, 2008 is hereby claimed under the provisions of 35 USC 119. The disclosures of said U.S. Provisional Patent Application No. 60/976,408 and U.S. Provisional Patent Application No. 61/050,181 are hereby incorporated herein by reference in their respective entireties.

### FIELD OF THE INVENTION

The present invention relates to metal precursors useful for deposition of silicon-, metal- and metalloid-containing films (including oxides, nitrides, oxynitrides, carbides, silicides and chalcogenides) on substrates such as microelectronic device wafers and structures, as well as to compositions containing such precursors, and to processes for forming such silicon-, metal- and metalloid-containing films on substrates.

### DESCRIPTION OF THE RELATED ART

In the use of chemical vapor deposition (CVD) and atomic layer deposition (ALD), as employed for manufacturing of semiconductor and microelectronic products, there is a continuing search for improved precursors for depositing conformal films of high-quality under advantageous process conditions of temperature, pressure, flow rates, concentrations, etc., to fabricate metallization, barrier layers, dielectrics, gate structures, etc. on the substrate.

Transition metal dialkylamides or silylamides have been used as CVD/ALD precursors to grow metal films, metal oxide films, metal nitride films, and M-O—Si or M-N—Si ternary films, wherein M is a suitable metal. The use of extremely bulky groups such as N(SiMe₃)₂ and N(SiMe₃)(t-Bu), wherein Me is methyl and t-Bu is tert-butyl, has allowed the formation of unusually low coordination numbers and oxidation states for many metals.

Corresponding compositions include: 4-coordinated Nb(IV), Zr(IV), Hf(IV), Cr(II), Cr(IV), Mo(IV) and Ge(IV); 3-coordinated M(III) species (M=Al, Ga, Sc, Ti, V, Cr, Fe, Sb and lanthanides); and 2-coordinated M(II) species (M=Mn, Co, Ni, Zn, Cd, Ge, Te, Hg) and M(I) (M=Au, Cu).

There is nonetheless a continuing need in the art for new metal precursors useful for forming such metal films, metal oxide films, metal nitride films, and M-O—Si and M-N—Si ternary films, at low temperatures (<400° C.) on wafers and microelectronic device structures, with high conformality and uniformity of coverage, with good volatilizability and transport properties.

### SUMMARY OF THE INVENTION

The present invention relates to precursors for deposition of silicon and metals on substrates such as wafers and microelectronic device structures, to reagent compositions comprising such precursors, and to processes for forming films on substrates using such precursors.

In one aspect, the invention relates to a precursor compound selected from among:

(I) metal silylamide precursors with one or more disilylazacycloalkyl ligand(s), of the formula (1A) RₙM{N[(R¹R²)Si(CR⁵R⁶)ₘSi(R³R⁴)]}ₒₓ₋ₙ;
metal amides including silylamido ligands with potential semi-labile pendent ligands of the formula (2A) RₙM(N(R¹R²))ₒₓ₋ₙ and (3A) RₙM{[Si(R³R⁴R⁵)NSi(R¹R²R³)]}ₒₓ₋ₙ.

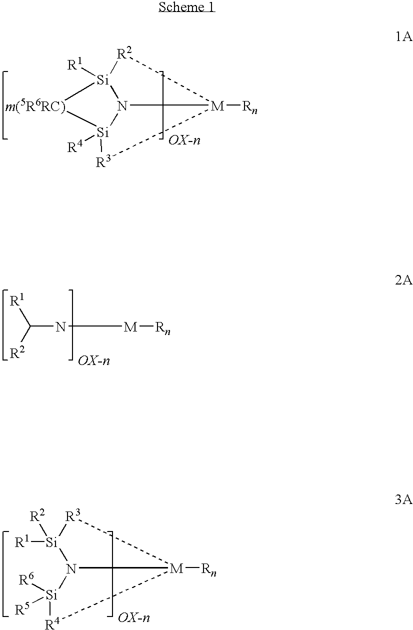

(II) guanidinate metal precursors of the formula (1B) RₙM{R^{.}NC[N((R¹R²)Si(CH₂)ₘSi(R³R⁴))]NR^{..})}ₒₓ₋ₙ; (2B) RₙM{R^{.}NC(N(R¹R²))NR^{..}}ₒₓ₋ₙ and (3B) RₙM{(R^{.}NC(Si(R⁴R⁵R⁶)N(Si(R¹R²R³))NR^{..}}ₒₓ₋ₙ.
formed by carbodiimide reaction with the metal silylamide precursors of (1A), (2A) and (3A).

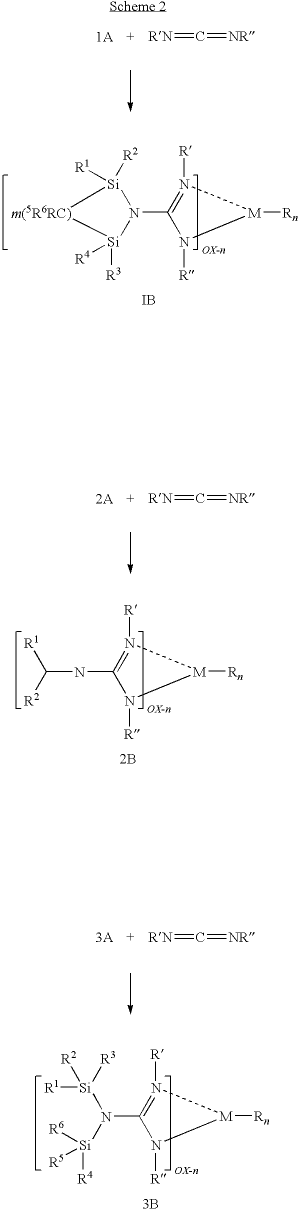

(III) oligomers of the metal guanidinate precursors (1B), of the formula [RₙM{R^{.}NC[N((R¹R²)Si(CH₂)ₘSi(R³R⁴))]NR^{..})}ₒₙ₋ₙ]ₓ, wherein x is an integer having a value of at least 2;
(IV) oligomers of the metal guanidinate precursors (2B), of the formula [RₙM{R^{.}NC(N(R¹R²))NR^{..}}ₒₓ₋ₙ]x, wherein x is an integer having a value of at least 2;
(V) oligomers of the metal guanidinate precursors (3B), of the formula [RₙM{(R^{.}NC(Si(R⁴R⁵R⁶)N(Si(R¹R²R³))NR^{..}}ₒₓ₋ₙ]x, wherein x is an integer having a value of at least 2;
(VI) metal precursors including a tetraalkylguanidine ligand, of the formula (4A) (R)ₙM {N═C[(NR¹R²)(NR³R⁴)]}ₒₓ₋ₙ;

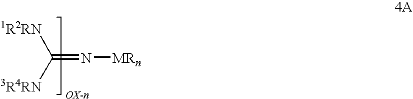

(VII) metal precursors including a tetraalkylguanidine ligand, coordinated in a semi-labile coordination mode (4B);

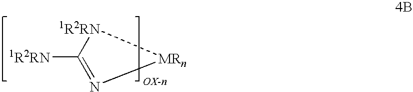

(VIII) a metal precursor composition comprising metal precursors of formula (4C);

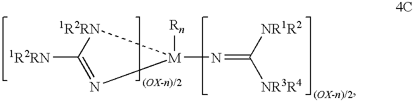

as shown in Scheme 3 below

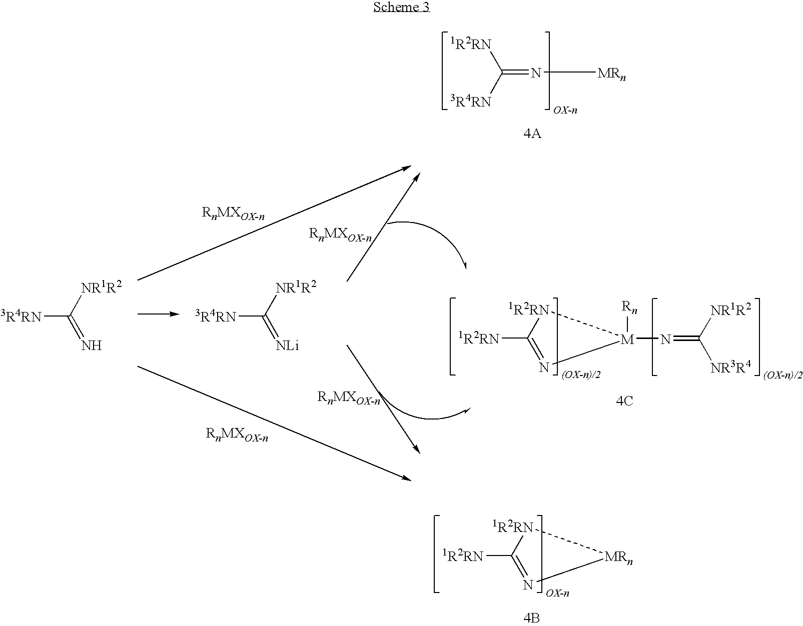

(IX) oligomers of the metal precursors of formula (4A), (4B) or (4C) having the formula [(R)ₙM{N═C[(NR¹R²)(NR³R⁴)]}ₒₓ₋ₙ]x, wherein x is an integer having a value of at least 2;
(X) guanidinate complexes of the formula (5) RₙM{R^{.}NC{N═C[(NR¹R²)(NR³R⁴)]}NR^{..}}ₒₓ₋ₙ

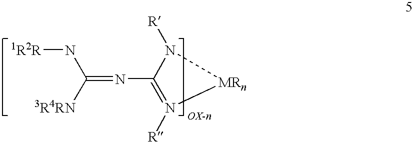

as shown in Scheme 4 below

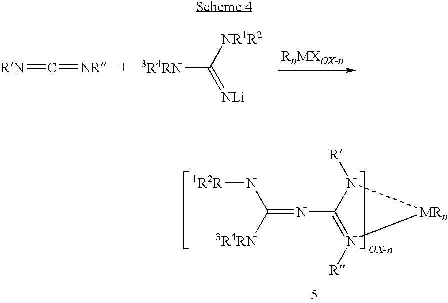

(XI) oligomers of the metal precursors of formula (5), having the formula [RₙM{R^{.}NC{N═C[(NR¹R²)(NR³R⁴)]}NR^{..}}ₒₓ₋ₙ]x, wherein x is an integer having a value of at least 2;
(XII) guanidinate complexes formed as a reaction product of metal amides by tetraalkylguanidine insertion reaction shown in Scheme 3;
(XIIII) ketimates of the formula (6A) (R)ₙM{N═C(R¹R²)}ₒₓ;

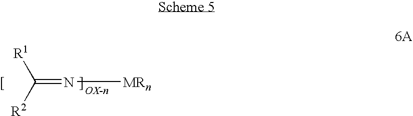

(XIV) guanidinate complexes of the formula (6B) RₙM{R^{.}NC[N═C(R¹R²)]NR^{..}}ₒₓ₋ₙ,

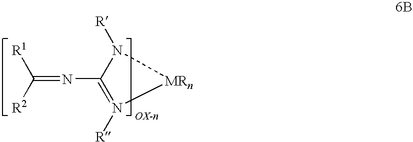

as shown in Scheme 6 below:

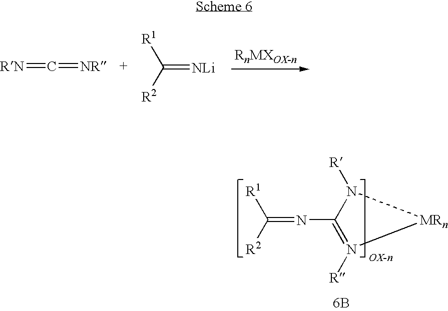

(XV) oligomers of the guanidinate complexes of formula (6B), having the formula [RₙM{R^{.}NC[N═C(R¹R²)]NR^{..}}ₒₓ₋ₙ]x wherein x is an integer having a value of at least 2;
(XVI) alkylchalcogenide complexes of the formula 7 (R¹R²R³)M′(ER⁴)

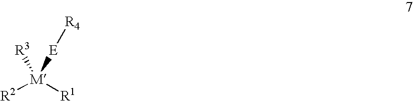

as can be formed by an insertion reaction wherein R¹ and R² are alkyl, amide, amidinate, or guanidinate ligands, such as insertion of R³(E)R⁴ into (R¹R²)NM′N(R³R⁴), as shown below

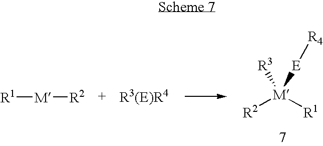

(XVII) dianionic guanidinate complexes of formula of (8).

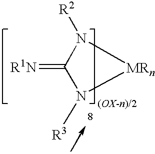

as shown in Scheme 8 below

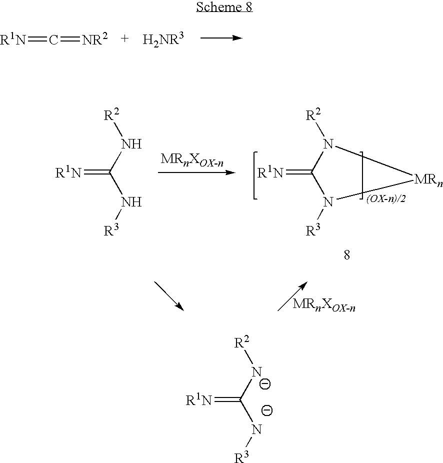

including complexes wherein the guanidinate ligand is singly deprotonated as shown below:

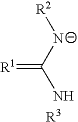

and forming complexes with coordination modes as shown below:

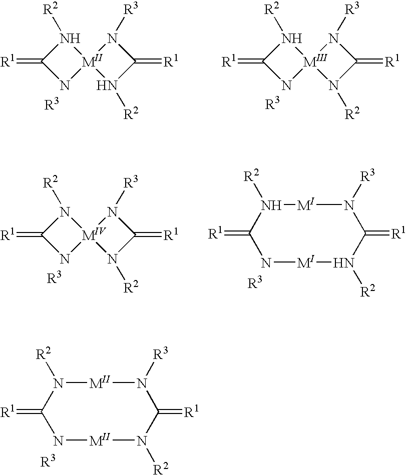

wherein:
M is a metal or metalloid, e.g., selected from among Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr and Ru;
M′ is a Group IV element, e.g., selected from among C, Si, Ge, Sn and Pb;
OX is the oxidation state of M and M′;
E is a Group VI element, e.g., selected from among O, S, Se and Te;
n is an integer having a value of from 0 to OX; and
m is an integer having a value of from 0 to 8;
wherein in respect of compounds (I)-(XV), each R(R¹, R², R³, R⁴, R⁵, R⁶, R⁷, R′, R″ and R) is independently selected from among H, C₁-C₆ alkyl, C₃-C₆ cycloalkyl, C₁-C₆ alkoxy, C₁-C₆ fluoroalkyl, amine, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{v}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl;
each of cyclopentadienyl substituents R^{I}, R^{III}, R^{III}, R^{IV}, and R^{V} can be the same as or different from the others, and is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to one or more of said R¹, R², R³, R⁴, R⁵, R⁶, R⁷, R′, R″ and R comprising functional group(s) providing further coordination to the metal center, and selected from among aminoalkyl, alkoxyalkyl, aryloxyalkyl, imidoalkyl, and acetylalkyl, having the following formulae:

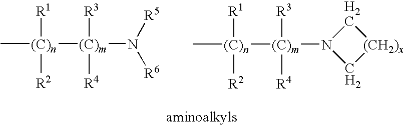

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

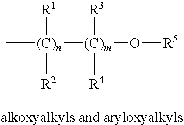

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

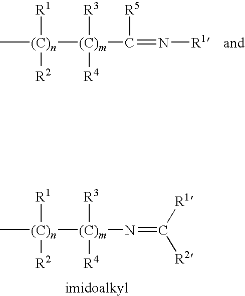

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

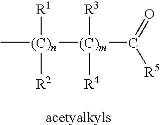

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

In a further aspect, the invention relates to a metal precursor selected from among the compounds of formulae IA, IB, 2A, 2B, 3A and 3B:

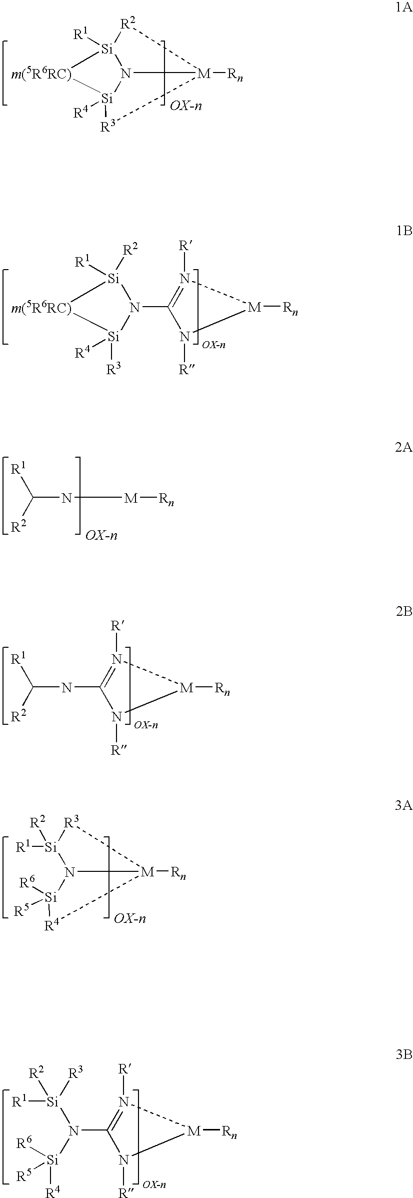

and to methods of making compounds of formulae 1B, 2B and 3B via an insertion reaction:

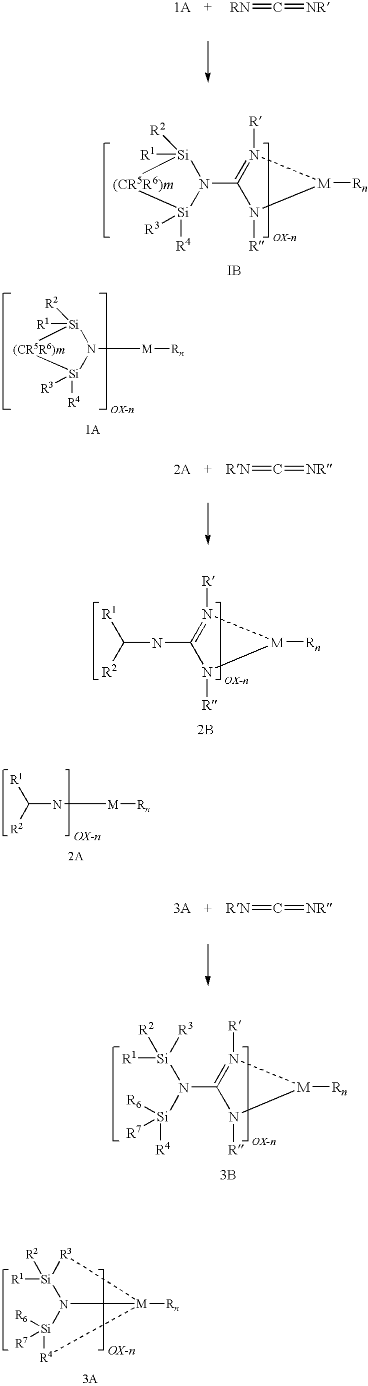

wherein:
M is a metal or a metalloid, e.g., a metal selected from among Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr and Ru;
OX is the oxidation state of the M;
n is an integer having a value of from 0 to OX;
m is an integer having a value of from 0 to 8;
wherein each R(R¹, R², R³, R⁴, R⁵, R⁶, R⁷, R′, R″ and R) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to said R¹, R², R³, R⁴, R⁵, R⁶, R⁷, R′, R″ and R comprising functional group(s) providing further coordination to the metal center, and selected from among aminoalkyl, alkoxyalkyl, aryloxyalkyl, imidoalkyl, and acetylalkyl, having the following formulae:

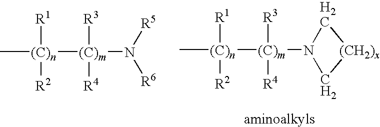

wherein: the methylene (—CH₂—) moiety could alternatively be another divalent hydrocarbyl moiety: each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

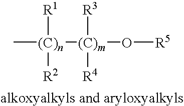

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

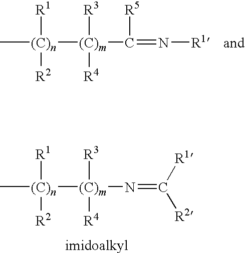

wherein each of R₁, R₂, R₃, R₄, R₅ is the same as or different from one another, with each being independently selected from among hydrogen, C₁-C₆ alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

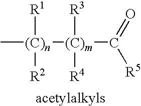

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

A further aspect of the invention relates to a precursor selected from among the compounds of formulae 4A, 4B, 4C, and 5, of the formulae:

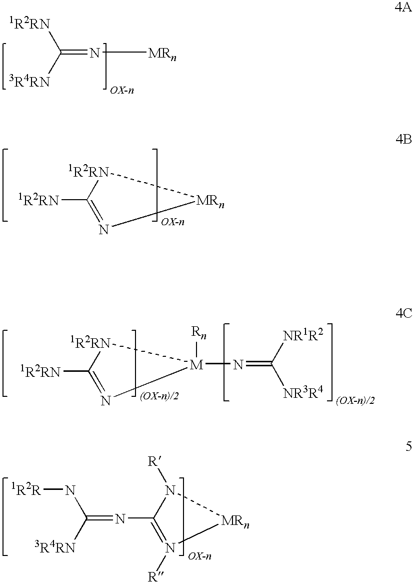

and method of making compounds of formulae 5 via an insertion reaction

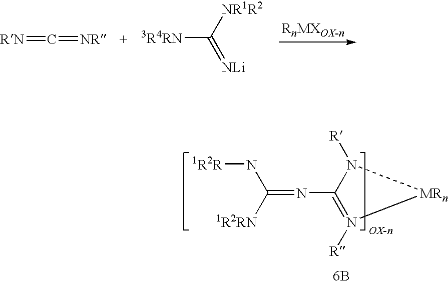

wherein:
M is a metal or metalloid, e.g., a metal selected from among Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr and Ru;
OX is the oxidation state of the M;
n is an integer having a value of from 0 to OX; and
wherein each R(R¹, R², R³, R⁴, R′, R″ and R) is independently selected from among H, C₁-C₆ alkyl, C₃-C₆ cycloalkyl, C₁-C₆ alkoxy, C₁-C₆ fluoroalkyl, amine, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}, R^{IV}R^{V}), wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to one or more of said R¹, R², R³, R⁴, R′, R″ and R comprising functional group(s) providing further coordination to the metal center, and selected from among aminoalkyl, alkoxyalkyl, aryloxyalkyl, imidoalkyl, and acetylalkyl, having the following formulae:

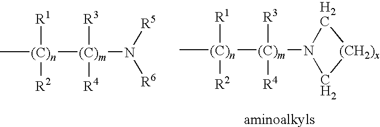

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

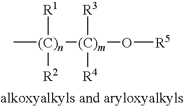

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

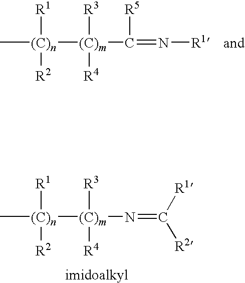

wherein each of R₁, R₂, R₃, R₄, R₅ is the same as or different from one another, with each being independently selected from among hydrogen, C₁-C₆ alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

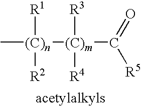

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time; and

A still further aspect of the invention relates to a precursor selected from among precursors of the formulae 6A and 6B

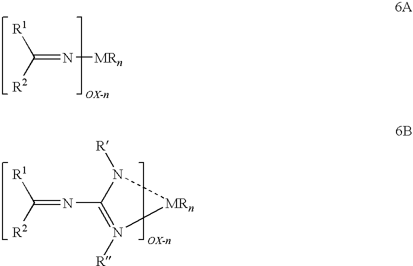

wherein:
M is a metal or metalloid, e.g., selected from among Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr and Ru;
OX is the oxidation state of the M;
n is an integer having a value of from 0 to OX; and
wherein each R(R¹, R², R′, R″ and R) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}), wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to one or more of said R¹, R², R′, R″ and R comprising functional group(s) providing further coordination to the metal center, and selected from among aminoalkyl, alkoxyalkyl, aryloxyalkyl, imidoalkyl, and acetylalkyl, having the following formulae:

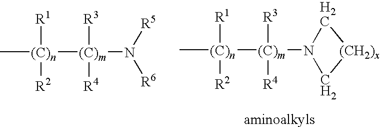

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

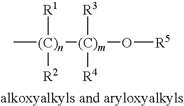

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

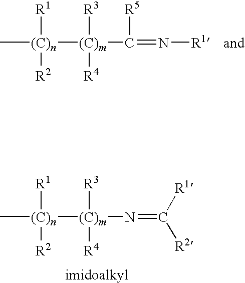

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

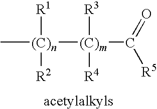

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time,
as well as a method of making a compound of the formula 6B by the insertion reaction:

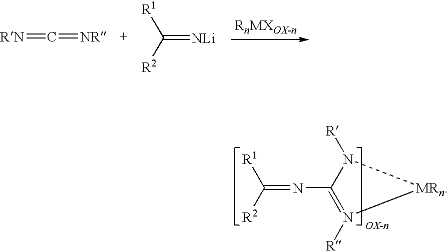

A still further aspect of the invention relates to a alkylchalcogenide precursor selected from among precursors of formula 7

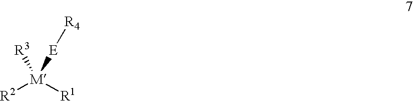

wherein:
R¹ and R² each independently selected from among alkyl, amide, amidinate, and guanidinate ligands,
as well as to a method of making such precursor via an insertion reaction, e.g., insertion of R³(E)R⁴ into (R¹R²)NM′(R³R⁴).

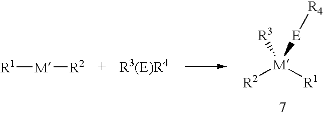

wherein:
M is a Group IV element, such as C, Si, Ge, Sn and Pb; OX is the oxidation state of M′;
E is a group VI element such as O, S, Se and Te wherein each R(R¹, R², R³, R⁴) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R_{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to one or more of said R¹, R², R³, R⁴ comprising functional group(s) providing further coordination to the metal center, and selected from among aminoalkyl, alkoxyalkyl, aryloxyalkyl, imidoalkyl, and acetylalkyl, having the following formulae:

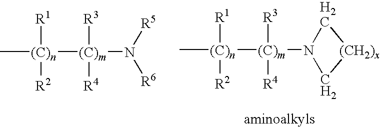

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

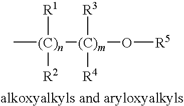

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

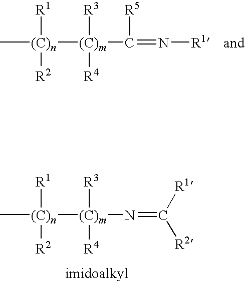

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

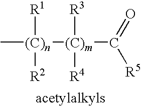

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

A still further aspect of the invention relates to a guanidine ligand selected from among precursors of the formula (8A)

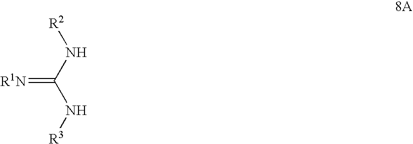

wherein each R(R¹, R², R³) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to said R¹, R² and R³, comprising functional group(s) providing further coordination to the metal center, and selected from among aminoalkyl, alkoxyalkyl, aryloxyalkyl, imidoalkyl, and acetylalkyl, having the following formulae:

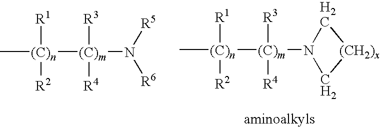

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

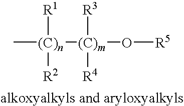

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

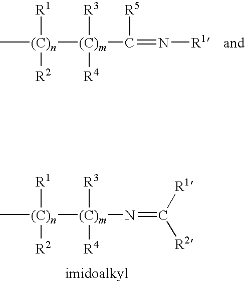

wherein each of R₁, R₂, R₃, R₄, R₅ is the same as or different from one another, with each being independently selected from among hydrogen, C₁-C₆ alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

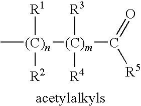

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time; and

A still further aspect of the invention relates to a precursor selected from among precursors of the formula (8)

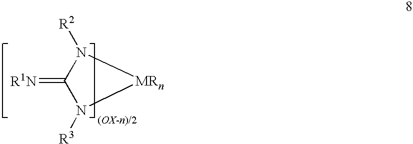

M is a metal or metalloid selected from among but not limited to Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr and Ru;
OX is the oxidation state of the M;
n is an integer having a value of from 0 to OX; and
wherein each R(R¹, R², R³, R) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to one or more of said R¹, R², R³ and R comprising functional group(s) providing further coordination to the metal center, and selected from among aminoalkyl, alkoxyalkyl, aryloxyalkyl, imidoalkyl, and acetylalkyl, having the following formulae:

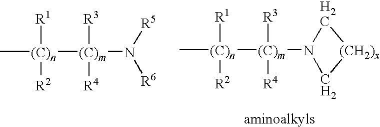

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

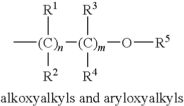

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

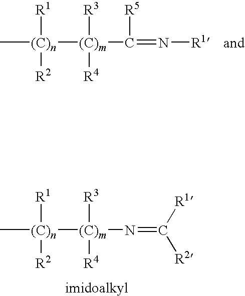

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

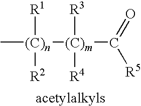

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time,

as well as a method of making such compound, by the reaction scheme including:

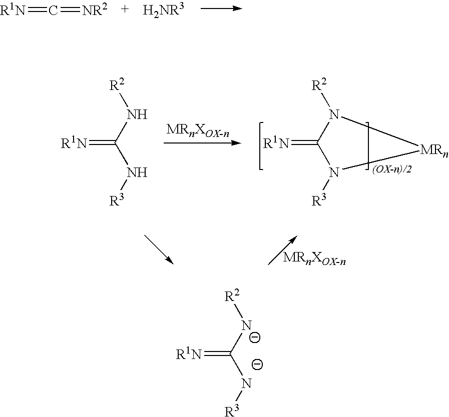

A still further aspect of the invention relates to a germanium precursor selected from among precursors of the formula (4A)

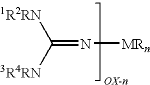

wherein each R (R¹, R², R³, R⁴ and R) is independently selected from among H, C₁-C₆ alkyl, C₃-C₆ cycloalkyl, C₁-C₆ alkoxy, C₁-C₆ fluoroalkyl, amine, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl;
each of cyclopentadienyl substituents R^{I}, R^{II}, R^{III}, R^{IV}, and R^{V} can be the same as or different from the others, and is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to one or more of said R¹, R², R³, R⁴ and R comprising functional group(s) providing further coordination to the metal center, and selected from among aminoalkyl, alkoxyalkyl, aryloxyalkyl, imidoalkyl, and acetylalkyl.

Specific compounds of such type include those set out below, according to another aspect of the invention:

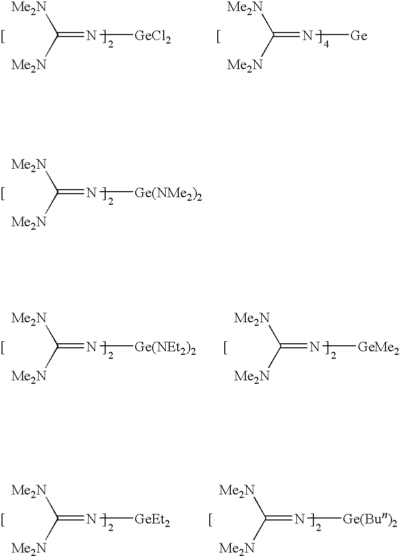

In still another aspect, the invention relates to iPrN═C(iPrNH)₂ wherein iPr is isopropyl, as an illustrative ligand species selected from among precursors of the formula (8A).

Yet another aspect of the invention relates to bis(2,2,5,5-tetramethyl-2,5-disila-1-azacyclopentanide)germanium (II), as an illustrative precursor species selected from among precursors of the formula (1A).

Another aspect of the invention relates to a method of making bis(2,2,5,5-tetramethyl-2,5-disila-1-azacyclopentanide)germanium (II), comprising:

(a) reacting butyllithium and a disilylamide of the formula:

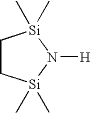

in a solvent medium comprising tetrahydrofuran, to yield a bis(disilylaminolithium)(thf) complex of the formula:

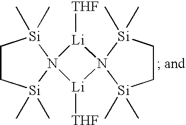

(b) reacting said bis(disilylaminolithium)(thf) complex in the presence of germanium dichloride and dioxane to produce said bis(2,2,5,5-tetramethyl-2,5-disila-1-azacyclopentanide)germanium (II).

The invention in a still further aspect relates to a compound of the formula:

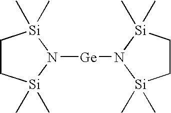

In another aspect, the invention relates to a method of making a germanium-guanidinate complex 1B-1 and -2, precursors selected from among precursors of the formula 1B:

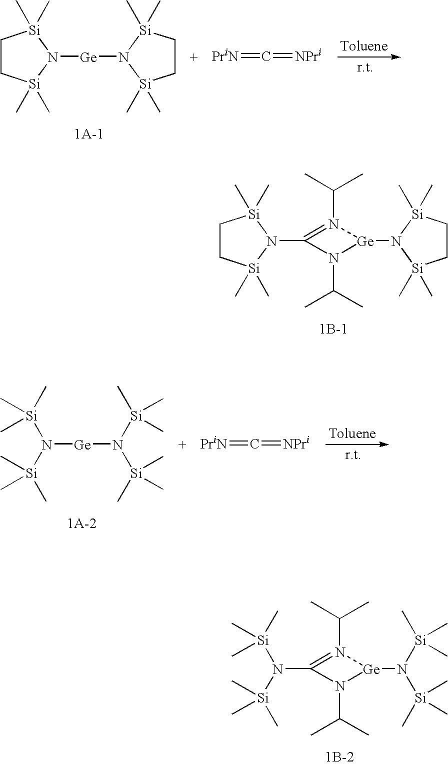

In another aspect, the invention relates to a method of making a germanium-silicon-tellurium complex of the formula as 7: said method comprising reacting bis(2,2,5,5-tetramethyl-2,5-disila-1-azacyclopentanide)germanium (II) with diisopropyl tellurium to form said germanium-silicon-tellurium complex.

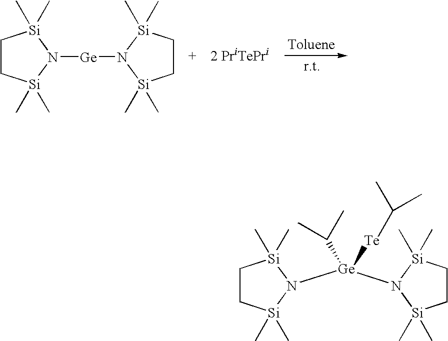

In another aspect, the invention relates to a method of making a guanidine of the formula 8A, said method comprising reacting carbodiimide with isopropylamine to form said guanidine by the reaction:

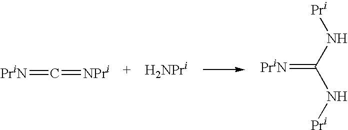

A further aspect of the invention relates to a method of forming a film on a substrate by chemical vapor deposition or atomic layer deposition, comprising use of a precursor of the present invention.

A further aspect of the invention relates to a method of forming a film on a substrate, e.g., by chemical vapor deposition or atomic layer deposition, pulse sequence, surface treatment, etc., comprising use of a reaction shown in any of the foregoing schemes, e.g., scheme 7 of the present invention.

In one additional aspect, the invention relates to a method of forming a germanium- and tellurium-containing film on a substrate, said method comprising volatilizing a precursor composition comprising bis(2,2,5,5-tetramethyl-2,5-disila-1-azacyclopentanide)germanium (II), to form a precursor vapor therefrom, and contacting said precursor vapor with a substrate under vapor deposition conditions, to form said germanium- and tellurium-containing film thereon.

In one aspect, the invention further relates to a method of combating pre-reaction of precursors described herein in a vapor deposition process for forming a film on a substrate, wherein the precursors described herein are susceptible to pre-reaction adversely affecting the film. In this aspect, the method involves introducing to the process a pre-reaction-combating agent selected from the group consisting of (i) heteroatom (O, N, S) organo Lewis base compounds, (ii) free radical inhibitors, and (iii) deuterium-containing reagents.

Another aspect of the invention relates to a method of combating pre-reaction of the precursors described in a vapor deposition process in which multiple feed streams are flowed to a deposition locus to form a film on a substrate, wherein at least one of said multiple feed streams includes a precursor susceptible to pre-reaction adversely affecting the film. The method involves introducing to at least one of said multiple feed streams or supplied materials therefor, or to the deposition locus, a pre-reaction-combating agent selected from the group consisting of (i) heteroatom (O, N, S) organo Lewis base compounds, (ii) free radical inhibitors, and (iii) deuterium-containing reagents.

A still further aspect of the invention relates to a composition, comprising a precursor as described herein and a pre-reaction-combating agent for said precursor, said pre-reaction-combating agent being selected from the group consisting of (i) heteroatom (O, N, S) organo Lewis base compounds, (ii) free radical inhibitors, and (iii) deuterium-containing reagents.

In a further aspect, the invention relates to a method of combating pre-reaction of a vapor phase precursor described herein in contact with a substrate for deposition of a film component thereon. The method involves contacting said substrate, prior to said contact of the vapor phase precursor therewith, with a pre-reaction-combating agent selected from the group consisting of (i) heteroatom (O, N, S) organo Lewis base compounds, (ii) free radical inhibitors, and (iii) deuterium-containing reagents.

In a further aspect, the invention relates to a process wherein the pre-reaction combating reagent is introduced to passivate the surface of a growing film or slow the deposition rate, followed by reactivation using an alternative precursor or co-reactant (for example H₂, NH₃, plasma, H₂O, hydrogen sulfide, hydrogen selenide, diorganotellurides, diorganosulfides, diorganoselenides, etc.). Such passivation/retardation followed by reactivation thus may be carried out in an alternating repetitive sequence, for as many repetitive cycles as desired, in ALD or ALD-like processes. Pre-reaction-combating agents can be selected from the group consisting of (i) heteroatom (O, N, S) organo Lewis base compounds, (ii) free radical inhibitors, and (iii) deuterium-containing reagents.

Another aspect of the invention relates to a vapor phase deposition process for forming a film on a substrate involving cyclic contacting of the substrate with at least one film precursor described herein that is undesirably pre-reactive in the vapor phase. The process involves introducing to said film during growth thereof a pre-reaction-combating reagent that is effective to passivate a surface of said film or to slow rate of deposition of said film precursor, and after introducing said pre-reaction-combating reagent, reactivating said film with a different film precursor.

Other aspects, features and embodiments of the invention will be more fully apparent from the ensuing disclosure and appended claims.

### BRIEF DESCRIPTION OF THE DRAWINGS

FIG. 1 is an ORTEP diagram of iPrN═C(iPrNH)₂.

FIG. 2 is the NMR plot for bis(2,2,5,5-tetramethyl-2,5-disila-1-azacyclopentanide)Lithium (LiTMDSACP)

FIG. 3 is an ORTEP diagram of LITMDSACP•THF.

FIG. 4 is an NMR plot for bis(2,2,5,5-tetramethyl-2,5-disila-1-azacyclopentanide)germanium (GeTMDSACP).

FIG. 5 is an STA plot for bis(2,2,5,5-tetramethyl-2,5-disila-1-azacyclopentanide)germanium (II) (GeTMDSACP).

FIG. 6 is an ORTEP diagram for Prⁱ(PrⁱTe)GeTMDSACP.

FIG. 7 is an NMR plot for Ge(II) telluro-germane, Prⁱ(PrⁱTe)GeTMDSACP.

FIG. 8 is an STA plot for Prⁱ(PrⁱTe)GeTMDSACP.

FIG. 9 is an ORTEP diagram for Ge(II) guanidinate 1B-1.

FIG. 10 is an NMR plot for Ge(II) guanidinate 1B-1.

FIG. 11 is an STA plot for Prⁱ(PrⁱTe)GeTMDSACP₂.

FIG. 12 is an ORTEP diagram for TMG₂GeCl₂.

FIG. 13 is an ORTEP diagram for TMG₂Ge(NMe₂)₂.

FIG. 14 is a schematic representation of a material storage and dispensing package containing a metal precursor, according to one embodiment of the present invention.

FIG. 15 is a schematic representation of a vapor deposition system according to one embodiment of the present invention, wherein suppression of pre-reaction of the precursors is achieved by addition of pre-reaction-combating reagent to one or more feed streams in the vapor deposition system.

### DETAILED DESCRIPTION OF THE INVENTION, AND PREFERRED EMBODIMENTS THEREOF

The present invention relates to metal precursors useful for deposition of silicon- and metal-containing films (including metal oxides, metal nitrides, metal oxynitrides, and metal chalcogenides) on substrates such as microelectronic device wafers and structures, as well as to compositions containing such precursors, and to processes for forming such silicon- and metal-containing films on substrates.

In one aspect, the present invention relates to transition metal silylamides, which are useful for deposition processes, such as chemical vapor deposition and atomic layer deposition, to form metal-containing films on substrates that are contacted with vapor of such precursors, subsequent to volatilization thereof.

Transition metal silylamides of the invention can utilize 4-coordinated metals such as Nb(IV), Zr(IV), Hf (IV), Cr(II), Cr(IV), Mo(IV) and Ge(IV); 3-coordinated M(III) species (M=Al, Ga, Sc, Ti, V, Cr, Fe, Sb and lanthanides); and 2-coordinated M(II) species (M=Mn, Co, Ni, Zn, Cd, Ge, Te, Hg) and M(I) (M′=Au, Cu). These transition metal complexes tend to exist as monomers or low-order oligomers, which is desirable in order for such complexes to be sufficiently volatile to be useful as CVD/ALD precursors. These complexes also can react with protic reagents to liberate amines, and are labile towards a number of insertion reactions, including carbodiimide insertion reactions that yield corresponding guanidinates.

In addition, such metal silylamide complexes in low coordination numbers also react with small unsaturated molecules such as NO and/or O₂, which affords advantages in CVD/ALD processes when single-source precursors are not suitable for forming films with specific desired compositional character.

Furthermore, the semi-labile versatility of the ligands can be used in stabilizing some low valent metal complexes that otherwise would not be stable enough to sustain practical delivery requirements in ALD/CVD processes.

In addition, the tunability in the ligand synthesis and formation of nitrogen- and silicon-rich films, such as tantalum nitride and silicon nitride films, make such precursors highly attractive for vapor deposition applications.

The present invention in specific additional aspects relates to precursors for deposition of silicon and metals on substrates such as wafers and microelectronic device structures, to reagent compositions comprising such precursors, and to processes for forming films on substrates using such precursors.

In one aspect, the invention relates to a precursor compound selected from among:

(I) metal silylamide precursors with one or more disilylazacycloalkyl ligand(s), of the formula (1A) RₙM{N[(R¹R²)Si(CR⁵R⁶)ₘSi(R³R⁴)]}ₒₓ₋ₙ;

metal amides including silylamido ligands with potential semi-labile pendent ligands of the formula (2A) RₙM(N(R¹R²))ₒₓ₋ₙ and (3A) RₙM{[Si(R³R⁴R⁵)NSi(R¹R²R³)]}ₒₓₙ.

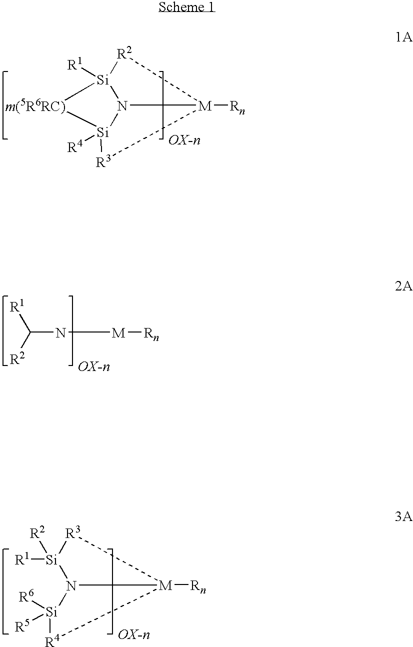

(II) guanidinate metal precursors of the formula (1B) RₙM{R^{.}NC[N((R¹R²)Si(CH₂)ₘSi(R³R⁴))]NR^{.})}ₒₓ₋ₙ; (2B) RₙM{R^{.}NC(N(R¹R²))NR^{.}}ₒₓ₋ₙ and (3B) RₙM{(R^{.}NC(Si(R⁴R⁵R⁶)N(Si(R¹R²R³))NR^{..}}ₒₓ₋ₙ.
formed by carbodiimide reaction with the metal silylamide precursors of (1A), (2A) & (3A).

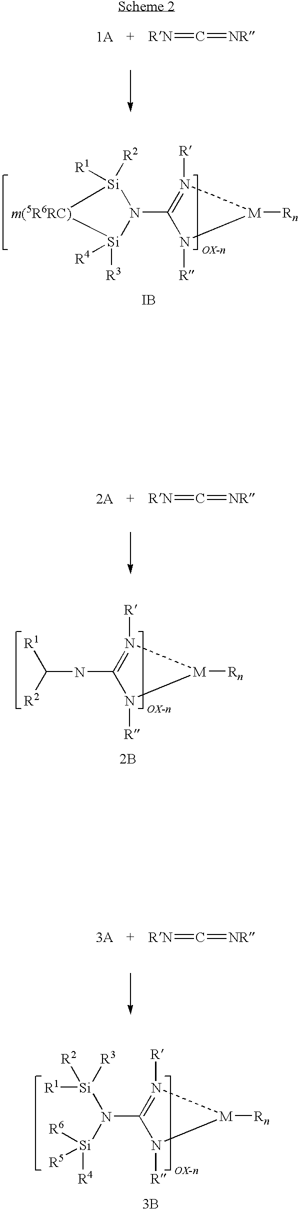

(III) oligomers of the metal guanidinate precursors (1B), of the formula [RₙM{R^{.}NC[N((R¹R²)Si(CH₂)ₘSi(R³R⁴))]NR^{..})}ₒₓ₋ₙ]x, wherein x is an integer having a value of at least 2;
(IV) oligomers of the metal guanidinate precursors (2B), of the formula [RₙM{R^{.}NC(N(R¹R²))NR^{..})}ₒₓ₋ₙ]x, wherein x is an integer having a value of at least 2;
(V) oligomers of the metal guanidinate precursors (3B), of the formula [RₙM{(R^{.}NC(Si(R⁴R⁵R⁶)N(Si(R¹R²R³))NR^{..}}ₒₓ₋ₙ]x, wherein x is an integer having a value of at least 2;
(VI) metal precursors including a tetraalkylguanidine ligand, of the formula (4A) (R)ₙM{N═C[(NR¹R²)(NR³R⁴)]}ₒₓ₋ₙ;

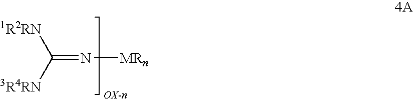

(VII) metal precursors including a tetraalkylguanidine ligand, coordinated in a semi-labile coordination mode (4B);

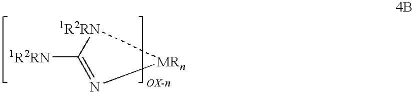

(VIII) a metal precursor composition comprising metal precursors of formula (4C);

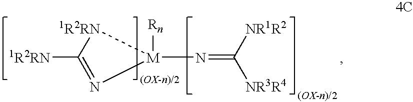

as shown in Scheme 3 below

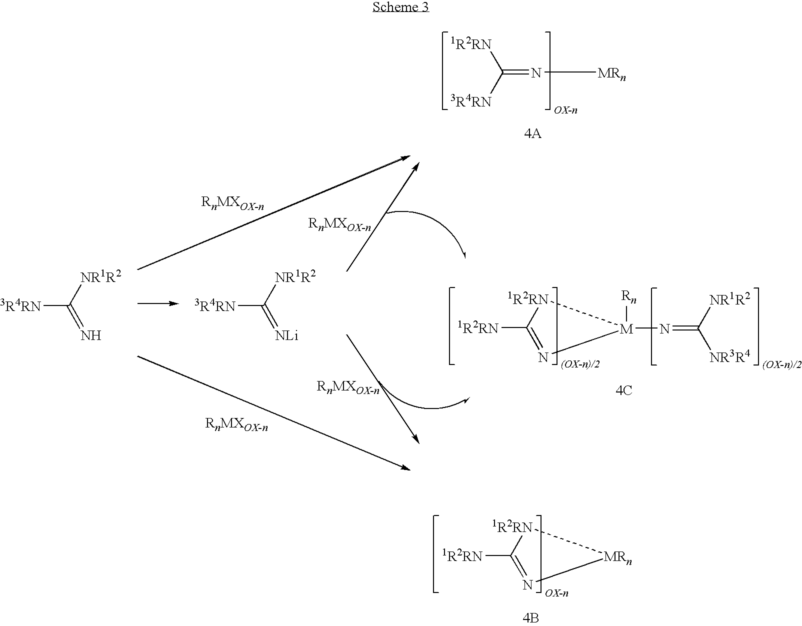

(IX) oligomers of the metal precursors of formula (4A), (4B) or (4C) having the formula [(R)ₙM{N═C[(NR¹R²)(NR³R⁴)]}ₒₓ₋ₙ]x wherein x is an integer having a value of at least 2;
(X) guanidinate complexes of the formula (5) RₙM{R^{.}NC{N═C[(NR¹R²)(NR³R⁴)]}NR^{∵}}ₒₓ₋ₙ

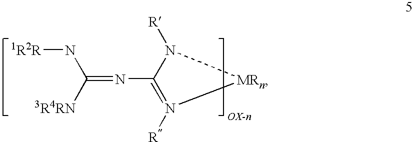

as shown in Scheme 4 below

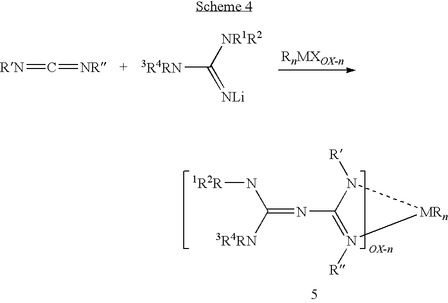

(XI) oligomers of the metal precursors of formula (5), having the formula [RₙM{R^{.}NC{N═C[(NR¹R²)(NR³R⁴)]})NR^{..}}ₒₓ₋ₙ]x, wherein x is an integer having a value of at least 2;
(XII) guanidinate complexes formed as a reaction product of metal amides by tetraalkylguanidine insertion reaction shown in Scheme 3;
(XIII) ketimates of the formula (6A) (R)ₙM{N═C(R¹R²)}ₒₓ;

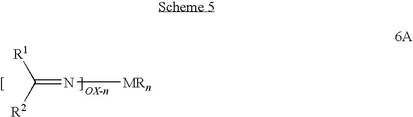

(XIV) guanidinate complexes of the formula (6B) RₙM{R^{.}NC[N═C(R¹R²)]NR^{..}}ₒₓ₋ₙ,

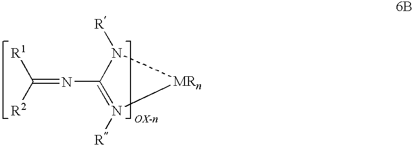

as shown in Scheme 6 below:

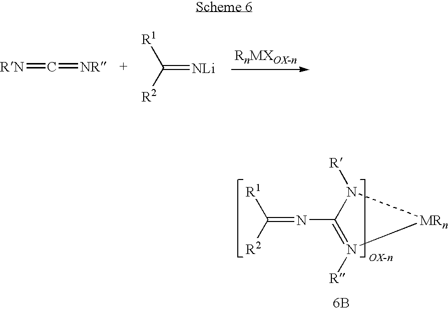

(XV) oligomers of the guanidinate complexes of formula (6B), having the formula [RₙM{R^{.}NC[N═C(R¹R²)]NR^{..}}ₒₓ₋ₙ]ₓ wherein k is an integer having a value of at least 2;
(XVI) alkylchalcogenide complexes of the formula 7 (R¹R²R³)M′(ER⁴)

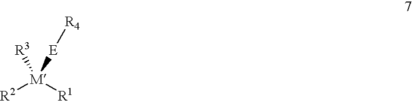

as can be formed by an insertion reaction wherein R¹ and R² are alkyl, amide, amidinate, or guanidinate ligands, such as insertion of R³(E)R⁴ into (R¹R²)NM′N(R³R⁴), as shown below

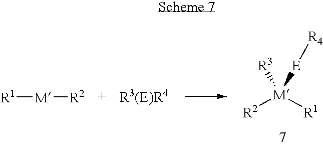

(XVII) dianionic guanidinate complexes of formula of (8)

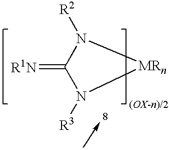

as shown in Scheme 8 below

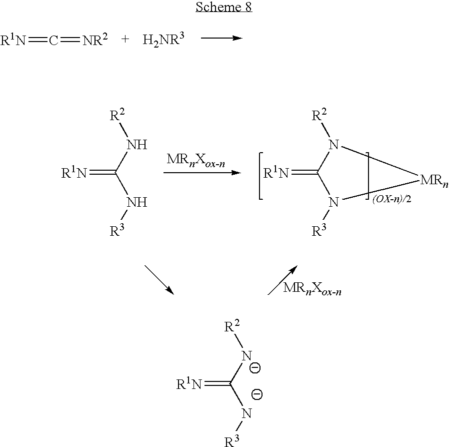

wherein:
M is a metal or metalloid, e.g., selected from among Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr and Ru;
M′ is a Group IV element, e.g., selected from among C, Si, Ge, Sn and Pb;
OX is the oxidation state of M and M′;
E is a Group VI element, e.g., selected from among O, S, Se and Te;
n is an integer having a value of from 0 to OX; and
m is an integer having a value of from 0 to 8;
wherein in respect of compounds (I)-(XV), each R(R¹, R², R³, R⁴, R⁵, R⁶, R′, R″ and R) is independently selected from among H, C₁-C₆ alkyl, C₃-C₆ cycloalkyl, C₁-C₆ alkoxy, C₁-C₆ fluoroalkyl, amine, aryloxyalkyl, imidoalkyl, acetylalkyl, NR^{a}R^{b}, C(R^{c})₃, —Si(R⁸)₃, —Ge(R¹)₃ and Cp-C(R^{I}R^{II}R^{III}R^{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl; Cp is cyclopentadienyl;
each of cyclopentadienyl substituents R^{I}, R^{II}, R^{III}, R^{IV}, and R^{V} can be the same as or different from the others, and is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl; optionally with pendant ligands attached to said R¹, R², R³, R⁴, R⁶ and R⁷ comprising functional group(s) providing further coordination to the metal center, and selected from among aminoalkyl, alkoxyalkyl, aryloxyalkyl, imidoalkyl, and acetylalkyl, having the following formulae:

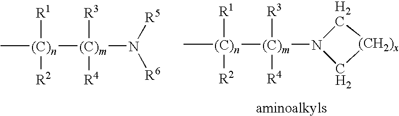

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

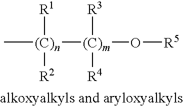

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

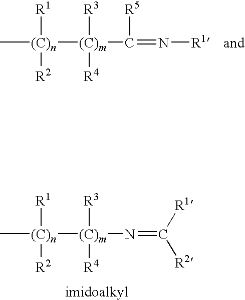

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

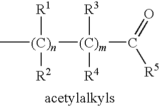

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

In a further aspect, the invention relates to a metal precursor selected from among the compounds of formulae IA, IB, 2A, 2B, 3A and 3B and methods of making 1B, 2B and 3B via an insertion reaction:

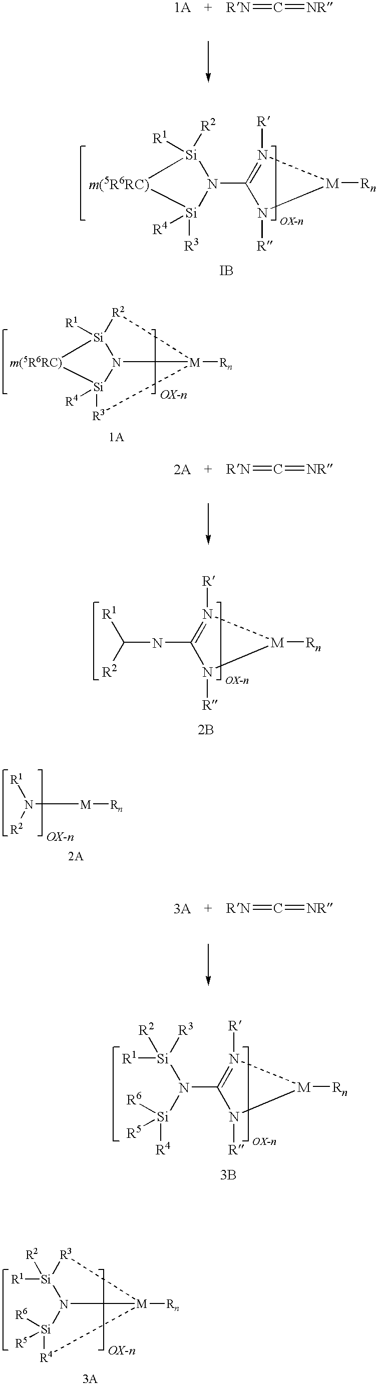

wherein:
M is a metal, e.g., Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr or Ru;
OX is the oxidation state of the M;
n is an integer having a value of from 0 to OX;
m is an integer having a value of from 0 to 8;
wherein each R(R¹, R²R³, R⁴, R⁵, R⁶, R⁷, R′, R″ and R) is independently selected from among H, C₁-C₆ alkyl, C₃-C₆ cycloalkyl, C₁-C₆ alkoxy, C₁-C₆ fluoroalkyl, amine, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, RII, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl; optionally with pendant ligands attached to said R¹, R², R³, R⁴, R⁶ and R⁷ comprising functional group(s) providing further coordination to the metal center, and selected from among aminoalkyl, alkoxyalkyl, aryloxyalkyl, imidoalkyl, and acetylalkyl, having the following formulae:

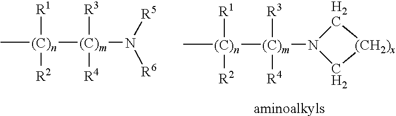

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

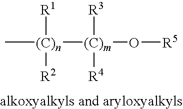

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

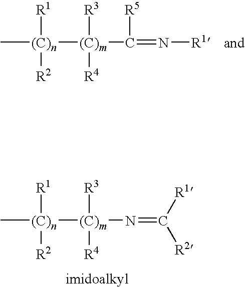

wherein each of R₁, R₂, R₃, R₄, R₅ is the same as or different from one another, with each being independently selected from among hydrogen, C₁-C₆ alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

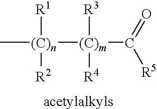

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

A further aspect of the invention relates to a precursor selected from among the compounds of formulae 4A, 4B, 4C, and 5 and method of making a compound of formula 5 via an insertion reaction:

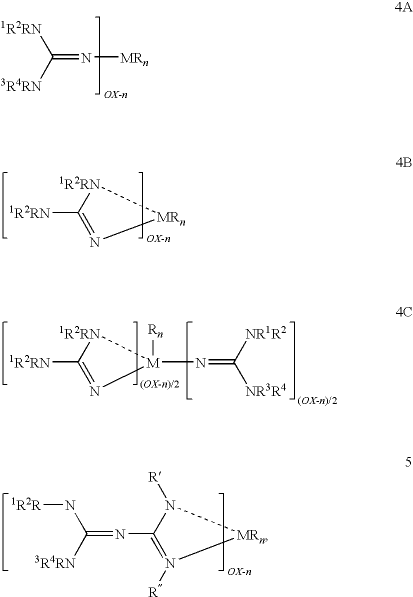

wherein:
M is a metal selected from among but not limited to Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr and Ru;
OX is the oxidation state of the M;
n is an integer having a value of from 0 to OX; and
wherein each R(R¹, R², R³, R⁴, R′, R″ and R) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}), wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to said R¹, R², R³, R⁴, R⁶ and R⁷ comprising functional group(s) providing further coordination to the metal center, and selected from among aminoalkyl, alkoxyalkyl, aryloxyalkyl, imidoalkyl, and acetylalkyl, having the following formulae:

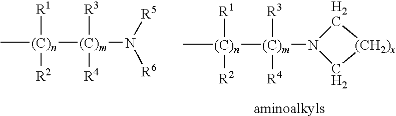

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

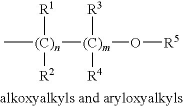

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

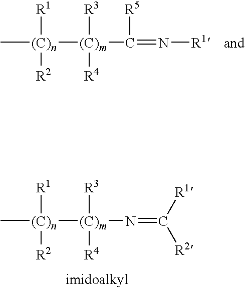

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

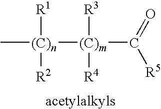

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

The formula 4A, 4B and 4C compounds can be synthesized according to the following reaction scheme:

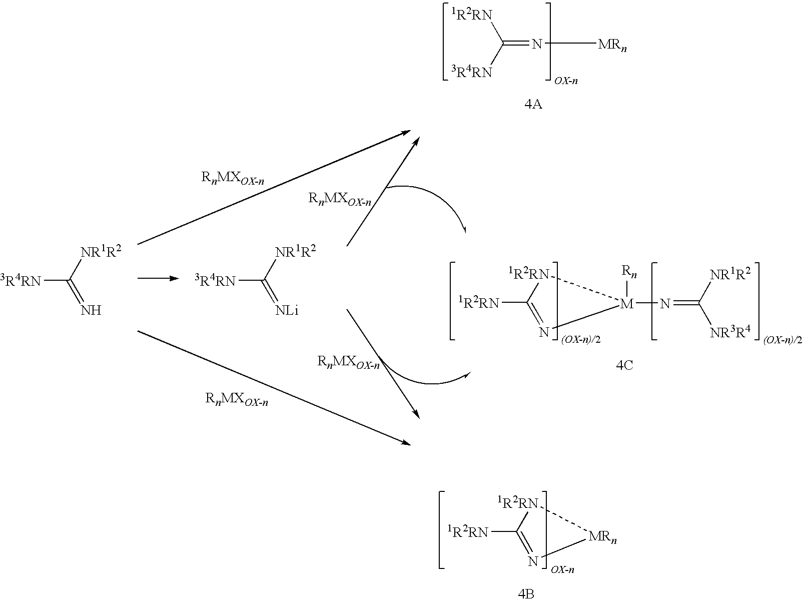

The compound of formula 5 can be synthesized according to the following reaction:

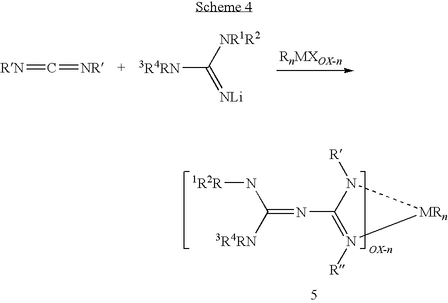

A still further aspect of the invention relates to a precursor selected from among precursors of the formula 6A and 6B, and the method of making 6B via an insertion reaction

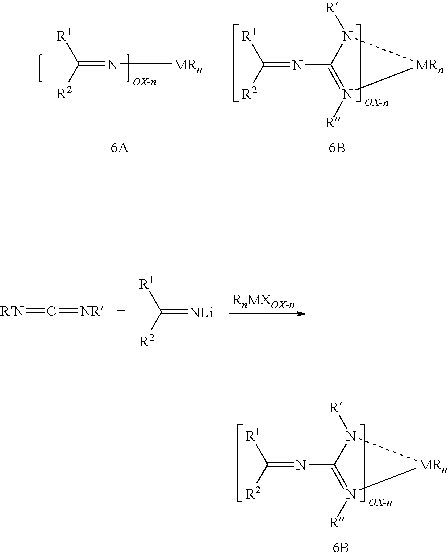

wherein:
M is a metal selected from among but not limited to Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr and Ru;
OX is the oxidation state of the M;
n is an integer having a value of from 0 to OX; and wherein each R(R¹, R², R′, R″ and R) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to said R¹, R², R³, R⁴, R⁶ and R⁷ comprising functional group(s) providing further coordination to the metal center, and selected from among aminoalkyl, alkoxyalkyl, aryloxyalkyl, imidoalkyl, and acetylalkyl, having the following formulae:

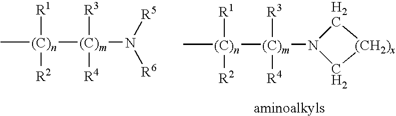

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

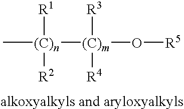

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

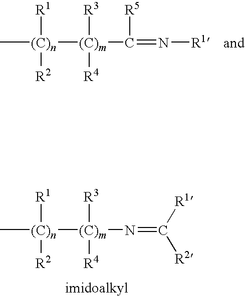

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

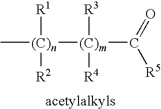

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

A still further aspect of the invention relates to a precursor selected from among precursors of the formula 7 and the method of making it via an insertion reaction; wherein R¹ and R² are alkyl, amide, amidinate, or guanidinate ligands, e.g., by insertion of R³(E)R⁴ into (R¹R²)NM′N(R³R⁴) by the following reaction:

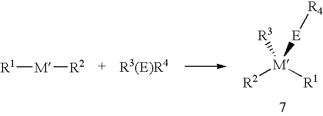

wherein:
M is a group IV element such as C, Si, Ge, Sn and Pb; OX is the oxidation state of the M;
E is a group VI element such as O, S, Se and Te;
wherein each R(R¹, R², R³, R⁴) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to said R¹, R², R³, R⁴, R⁶ and R⁷ comprising functional group(s) providing further coordination to the metal center, and selected from among aminoalkyl, alkoxyalkyl, aryloxyalkyl, imidoalkyl, and acetylalkyl, having the following formulae:

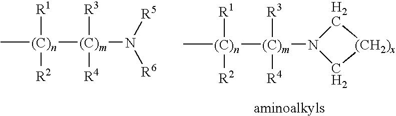

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

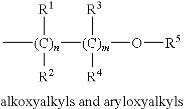

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

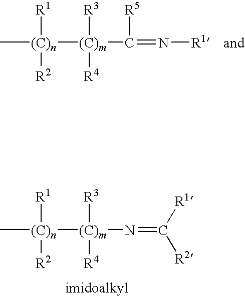

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆alkyl, and C₆-C₁₀ aryl; and n and m are selected independently from 0 to 4, with the proviso that m and n cannot be 0 at the same time;

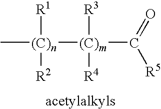

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

A still further aspect of the invention relates to a guanidine ligand selected from among precursors of the formula (8A)

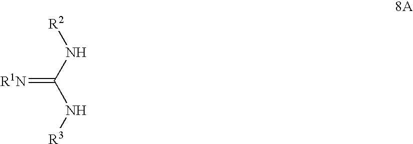

wherein each R (R¹, R², R³) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR^{a}R^{b}, C(R^{c})₃, —Si(R⁸)₃, —Ge(R⁸)₃ and Cp-C(R^{I}R^{II}R^{III}R^{IV}R^{V}),
wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to said R¹, R² and R³ comprising functional group(s) providing further coordination to the metal center, and selected from among aminoalkyl, alkoxyalkyl, aryloxyalkyl, imidoalkyl, and acetylalkyl, having the following formulae:

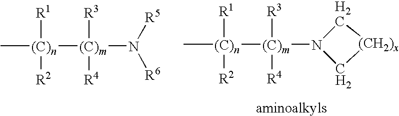

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

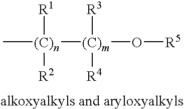

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

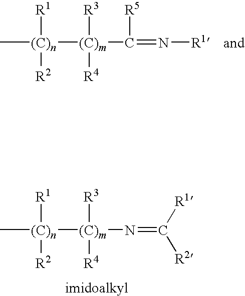

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

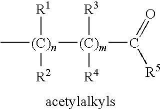

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

A still further aspect of the invention relates to a precursor selected from among precursors of the formula (8) and the methods of making it.

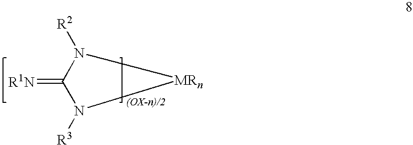

wherein:
M is a metal selected from among but not limited to Ta, V, Ti, Nb, Pb, Ni, W, Ca, Ba, In, Y, La, Zr, Hf, Ir, Ru, Pt, Cr, Mo, Ge; Al, Si, Ga, Sc, V, Cr, Fe, Sb, Bi, lanthanides, Mn, Co, Ni, Zn, Cd, Te, Hg, Au, Cu, Ag, Sr and Ru;
OX is the oxidation state of the M;
n is an integer having a value of from 0 to OX; and
wherein each R(R¹, R², R³, R) is independently selected from among H, C₁-C₆ alkyl, C₃-C₆ cycloalkyl, C₁-C₆ alkoxy, C₁-C₆ fluoroalkyl, amin, aryloxyalkyl, imidoalkyl, acetylalkyl, —NR¹R², C(R³)₃, —Si(R⁸)₃, —Ge(R⁸)₃ and Cp-C(R^{I}R^{II}R^{III}R^{IV}R^{V}),
wherein each R³ is independently selected from C₁-C₆ alkyl; and each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl; each of cyclopentadienyl substituents R^{I}, R^{II}, R^{III}, R^{IV}, and R^{V} may be the same as or different from the others, and is independently selected from among C₁-C₆alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to said R¹, R², R³ and R comprising functional group(s) providing further coordination to the metal center, and selected from among aminoalkyl, alkoxyalkyl, aryloxyalkyl, imidoalkyl, and acetylalkyl, having the following formulae:

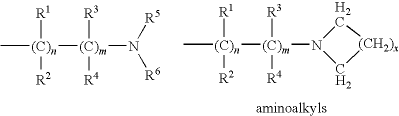

wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5;

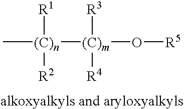

wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time;

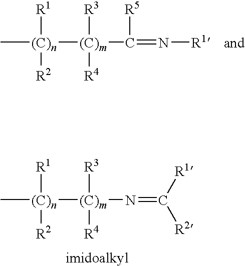

wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time;

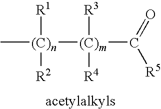

wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time; and

A still further aspect of the invention relates to a germanium precursor selected from among precursors of the formula (4A), e.g., precursors such as:

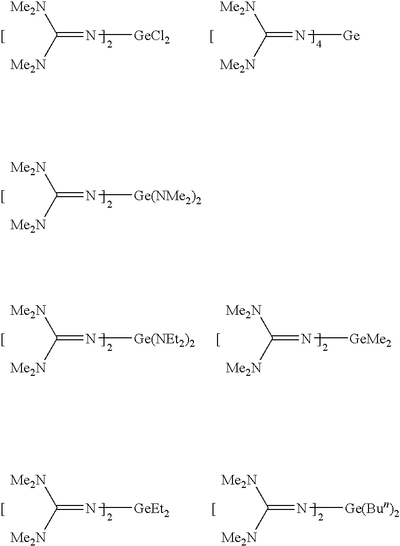

In still another aspect, the invention relates to iPrN═C(iPrNH)₂, a ligand selected from among ligands of the formula (8A), wherein iPr is isopropyl.

Yet another aspect of the invention relates to bis(2,2,5,5-tetramethyl-2,5-disila-1-azacyclopentanide)germanium (II), a precursor selected from among precursors of the formula as (1A).

Another aspect of the invention relates to a method of making bis(2,2,5,5-tetramethyl-2,5-disila-1-azacyclopentanide)germanium (II), comprising:

(a) reacting butyllithium and a disilylamide of the formula:

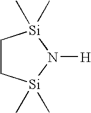

in a solvent medium comprising tetrahydrofuran, to yield a bis(disilylaminolithium)(thf) complex of the formula:

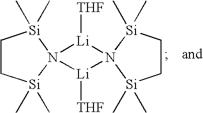

(b) reacting said bis(disilylaminolithium)(thf) complex in the presence of germanium dichloride and dioxane to produce said bis(2,2,5,5-tetramethyl-2,5-disila-1-azacyclopentanide)germanium (II).

The invention in a still further aspect relates to a compound of the formula:

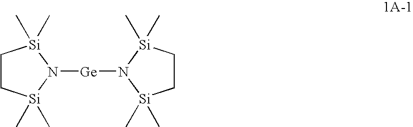

wherein THF is tetrahydrofuran.

In another aspect, the invention relates to a method of making a germanium-guanidinate complexes 1B-1 and 2 of the formula as 1B:

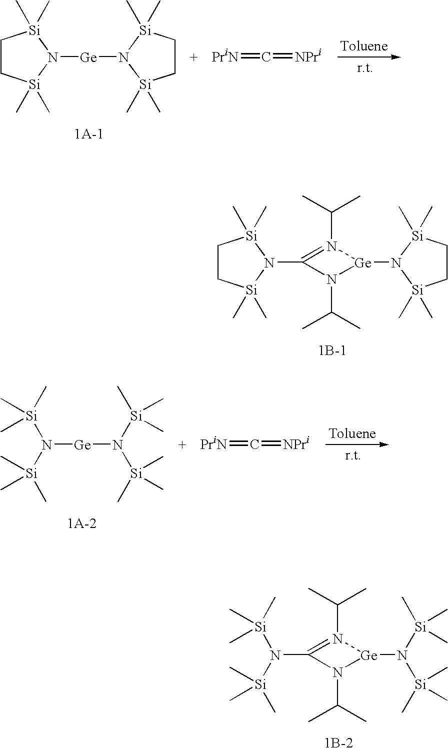

In another aspect, the invention relates to a method of making a germanium-silicon-tellurium complex of the formula 7, by a method comprising reacting bis(2,2,5,5-tetramethyl-2,5-disila-1-azacyclopentanide)germanium (II) with diisopropyl tellurium to form said germanium-silicon-tellurium complex.

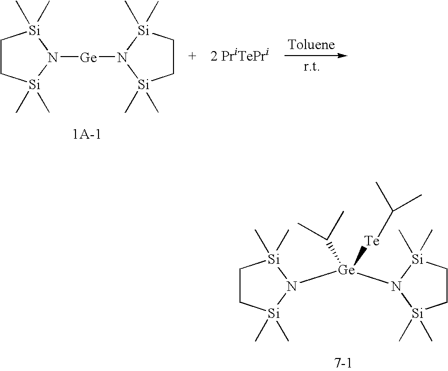

In another aspect, the invention relates to a method of making a guanidine of the formula 8A by the method comprising reacting carbodiimide with isopropylamine to form such guanidine.

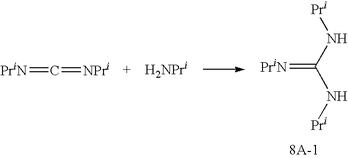

A further aspect of the invention relates to a method of forming a film on a substrate by chemical vapor deposition or atomic layer deposition, comprising use of a precursor of the present invention.

In one additional aspect, the invention relates to a method of forming a germanium- and tellurium-containing film on a substrate, such method comprising volatilizing a precursor composition comprising bis(2,2,5,5-tetramethyl-2,5-disila-1-azacyclopentanide)germanium (II), to form a precursor vapor therefrom, and contacting said precursor vapor with a substrate under vapor deposition conditions, to form said germanium- and tellurium-containing film thereon.

The above-described precursors are usefully employed for low temperature (<400° C.) vapor deposition precursors, being readily volatilizable to form a corresponding precursor vapor that then can be contacted with a substrate such as a wafer or microelectronic device structure.

Such low temperature vapor deposition processes can be carried out using the precursors of the invention, optionally with co-reactants or other deposition-enhancing components, such as hydrogen, H₂/plasma, amines, imines, hydrazines, silanes, silyl chalcogenides such as (Me₃Si)₂Te, germanes such as GeH₄, ammonia, alkanes, alkenes, amidines, guanidines, boranes and their derivatives/adducts and alkynes.

The above-described precursors can be utilized in liquid delivery formulations. Precursors that are liquids can be used in neat liquid form, or liquid or solid precursors may be employed in precursor solutions or suspensions using suitable media. The solvent media can include any suitable solvents, including, without limitation, alkane solvents (e.g., hexane, heptane, octane, and pentane), aryl solvents (e.g., benzene or toluene), amines (e.g., triethylamine, tert-butylamine), imines, guanidines, amidines, hydrazines, glymes, aliphatic hydrocarbons, aromatic hydrocarbons, ethers, amines, amides, esters, nitriles, and alcohols.

The utility of specific solvent compositions for particular precursors may be readily empirically determined, to select an appropriate single component or multiple component solvent medium for the liquid delivery vaporization.

The metal precursors of formulae 1-8 are readily synthesized from the corresponding alkali metal salts with metal halides, amides, or alkyls or mixed halides/amides/alkyls or from direct reactions between guanidines with metal halides with the presence of HX absorbents such as NEt₃, wherein, Et is ethyl. The synthesis of the guanidinate ligands can in turn be carried out using the corresponding carbodiimides and primary amines.

The above-described precursors are usefully employed for low temperature (<400° C.) vapor deposition precursors, being readily volatilizable to form a corresponding precursor vapor that then can be contacted with a substrate such as a wafer or microelectronic device structure.

Such low temperature vapor deposition processes can be carried out using the precursors of the invention, optionally with co-reactants or other deposition-enhancing components, such as hydrogen, H₂/plasma, amines, imines, hydrazines, silanes, silyl chalcogenides such as (Me₃Si)₂Te, germanes such as GeH₄, ammonia, alkanes, alkenes, amidines, guanidines, boranes and their derivatives/adducts and alkynes.

The above-described precursors can be utilized in liquid delivery formulations. Precursors that are liquids can be used in neat liquid form, or liquid or solid precursors may be employed in precursor solutions or suspensions using suitable media. The solvent media can include any suitable solvents, including, without limitation, alkane solvents (e.g., hexane, heptane, octane, and pentane), aryl solvents (e.g., benzene or toluene), amines (e.g., triethylamine, tert-butylamine), imines, guanidines, amidines, hydrazines, glymes, aliphatic hydrocarbons, aromatic hydrocarbons, ethers, amines, amides, esters, nitriles, and alcohols.

The utility of specific solvent compositions for particular precursors may be readily empirically determined, to select an appropriate single component or multiple component solvent medium for the liquid delivery vaporization.

In another aspect of the invention, a solid delivery system may be utilized to deliver the aforementioned precursors, such as the ProE-Vap solid delivery and vaporizer unit (commercially available from ATMI, Inc., Danbury, Conn., USA).

The various precursors of the invention may be usefully employed to form films on substrates by processes such as chemical vapor deposition or atomic layer deposition. In such processes, the vapor deposition may be carried out with a co-reagent such as hydrogen, H₂/plasma, amines, imines, hydrazines, silanes, silyl chalcogenides such as (Me₃Si)₂Te, germanes, GeH₄, ammonia, alkanes, alkenes, alkynes, amidines, guanidines, boranes or their derivatives and adducts.

Depending on the form of the precursors of the invention, CVD or ALD, or other vapor deposition processes, can be carried out with suitable delivery techniques for the precursor, e.g., liquid delivery techniques or solid delivery techniques. The vapor deposition processes of the invention can be carried out at low temperatures, e.g., temperature below 400° C.

A further aspect of the invention relates to a method of forming a film on a substrate by chemical vapor deposition or atomic layer deposition, pulse sequence, surface treatment, etc., comprising use of a reaction such as shown in any of the foregoing schemes, especially Scheme 7 of the present invention.

In one specific embodiment, the invention contemplates forming a germanium- and tellurium-containing film on a substrate, such method comprising volatilizing a precursor composition comprising bis(2,2,5,5-tetramethyl-2,5-disila-1-azacyclopentanide)germanium (II), to form a precursor vapor therefrom, and contacting the precursor vapor with a substrate under vapor deposition conditions, to form the germanium- and tellurium-containing film thereon.

Such method may be carried out with bis(2,2,5,5-tetramethyl-2,5-disila-1-azacyclopentanide)germanium (II) in neat form, by liquid delivery from a suitable source of the reagent, to a vaporizer in which the precursor is volatilized to form a precursor vapor which then is contacted with the substrate such as a wafer or other microelectronic device structure. The vapor deposition contacting of the precursor vapor with the substrate preferably is carried out at temperature below 400° C.

The invention in a further aspect relates to a metal precursor in which the metal central atom is coordinated to multiple ligands including one or more of the ligands variously described herein, wherein when the number of ligands is two or more, the ligands can be the same as or different from one another.

The advantages and features of the invention are further illustrated with reference to the following examples, which are not to be construed as in any way limiting the scope of the invention but rather as illustrative of illustrative embodiments of the invention in specific applications thereof.

### Example 1

An exemplary ligand iPrN═C(iPrNH)₂ wherein iPr is isopropyl was synthesized and characterized by the following procedure.

To a 250 mL flask charged with 12.6 g iPrNCNiPr (0.1 mol) and 100 ml toluene, 5.9 g iPrNH₂ (0.1 mol) was added at 0° C. gradually. The resulting mixture was then refluxed at 100° C. overnight. After work-up, 11.5 g solid iPrN═C(iPrNH)₂ was obtained (62% yield). Anal. calculated for C₁₀H₂₃N₃: C, 64.81%; H, 12.51%; N, 22.68%; found: C, 64.73%; H, 12.39%; N, 22.48%.

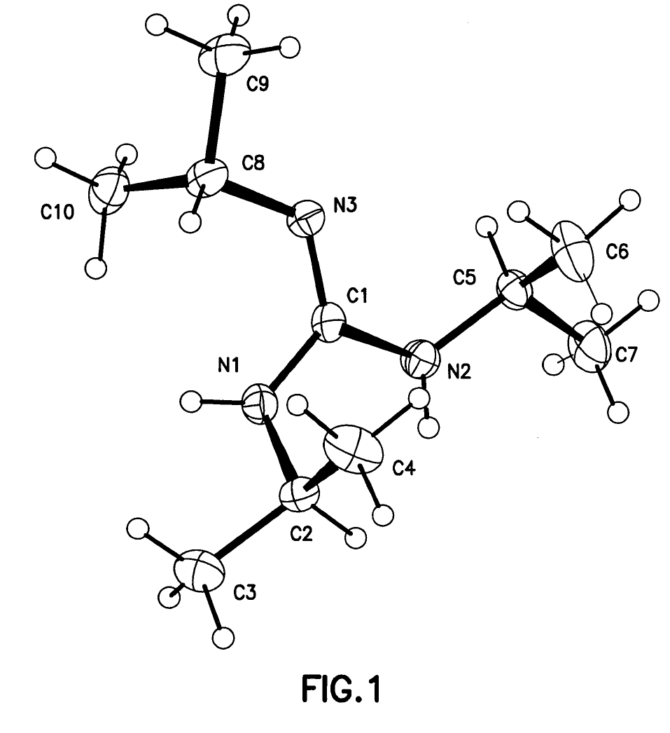

The crystal structure of the product is shown in the ORTEP representation of FIG. 1. The selected bond lengths of the compound [Å] were determined as:

| | |
|---|---|
| C(1)—N(3) | 1.287(3) |
| C(1)—N(2) | 1.358(3) |
| C(1)—N(1) | 1.378(3) |

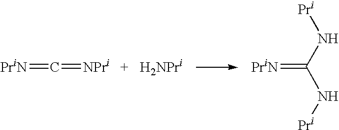

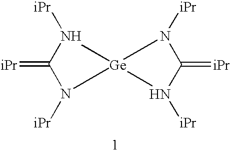

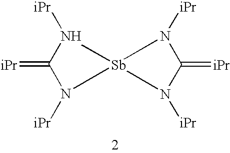

| Compound | | C (%) | H (%) | N (%) |
|---|---|---|---|---|
| 1 | Calculated | 46.62 | 8.27 | 16.42 |
| | Found | 46.62 | 8.11 | 16.17 |
| 2 | Calculated | 49.09 | 8.86 | 17.17 |
| | Found | 49.22 | 8.96 | 17.24 |

### Example 2

### Synthesis and Characterization of GeTMDSACP

Bis(2,2,5,5-tetramethyl-2,5-disila-1-azacyclopentanide)germanium (II), denoted GeTMDSACP, was synthesized by the synthetic route set out below.

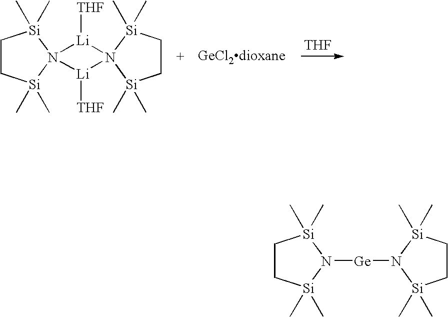

The intermediate product, LITMDSACP

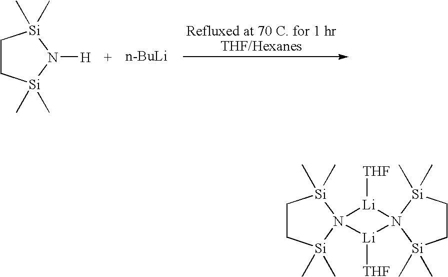

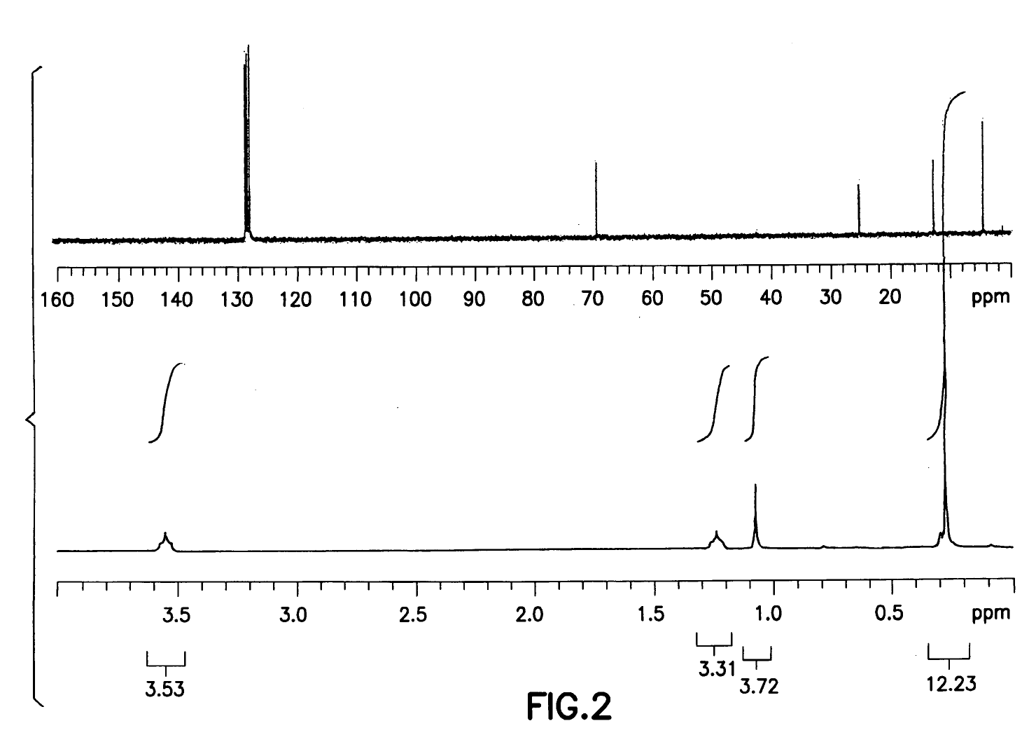

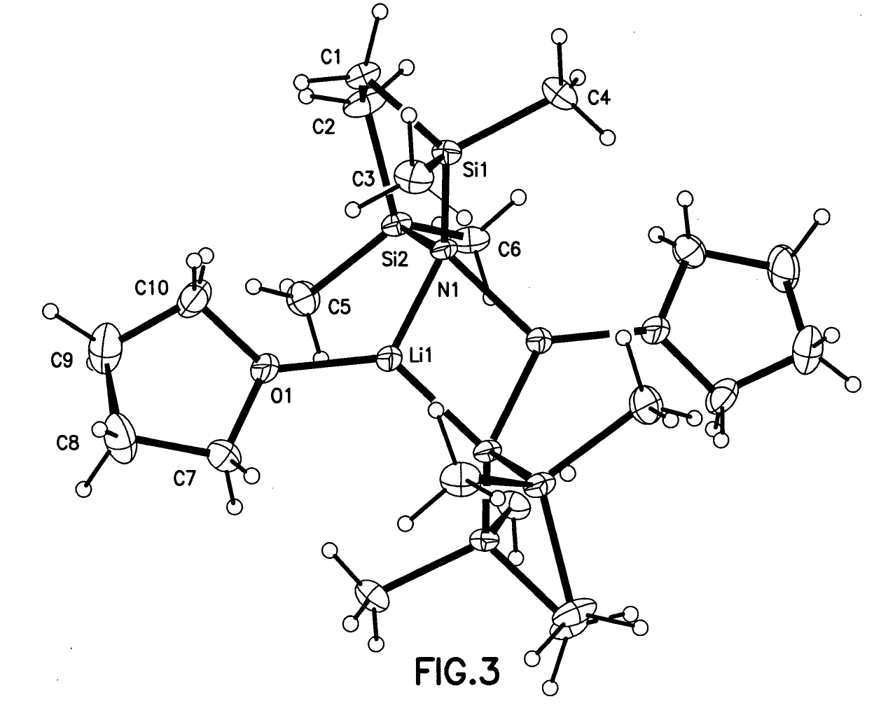

was characterized and determined to have the NMR spectrum shown in FIG. 2 hereof. The ORTEP representation for this compound is set out in FIG. 3 hereof.

The calculated and empirically determined component values are set out in Table 2 below.

TABLE 2

| LiTMDSACP | C (%) | H (%) | N (%) |
|---|---|---|---|
| Calculated | 50.60 | 10.19 | 5.90 |
| Found | 50.59 | 10.28 | 5.93 |

The final product, GeTMDSACP,

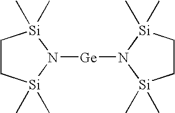

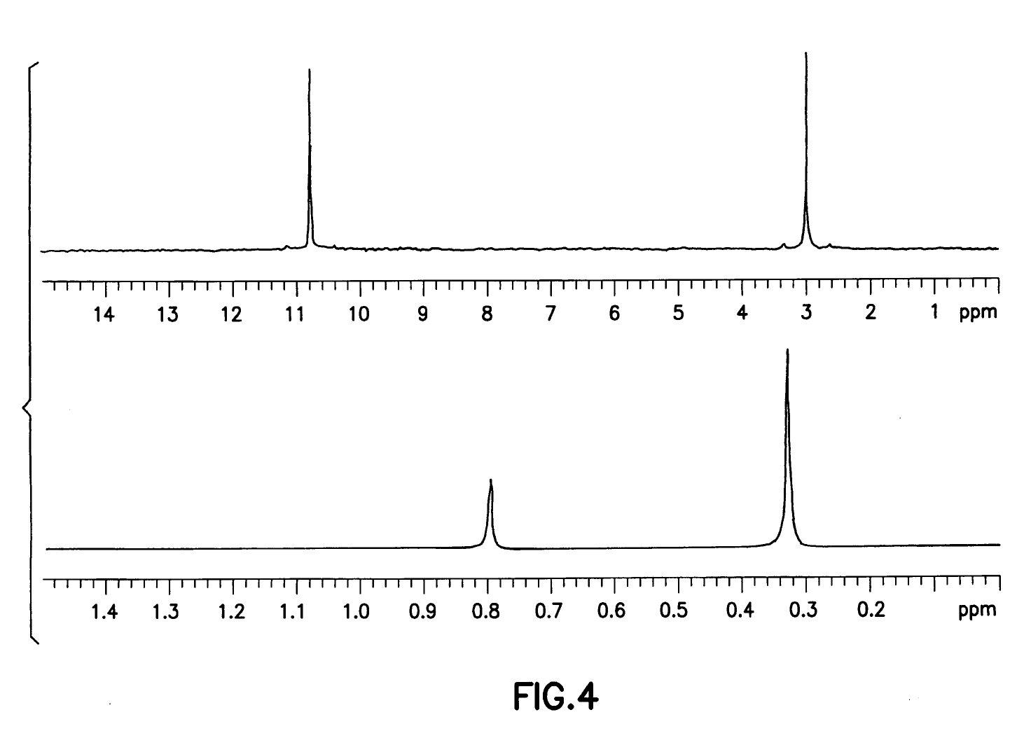

was recovered as an orange-red liquid with the NMR spectrum shown in FIG. 4. The calculated and empirically determined component values are set out in Table 3 below.

TABLE 3

| GeTMDSACP | C (%) | H (%) | N (%) |
|---|---|---|---|
| Calculated | 37.02 | 8.28 | 7.19 |
| Found | 36.92 | 8.17 | 7.26 |

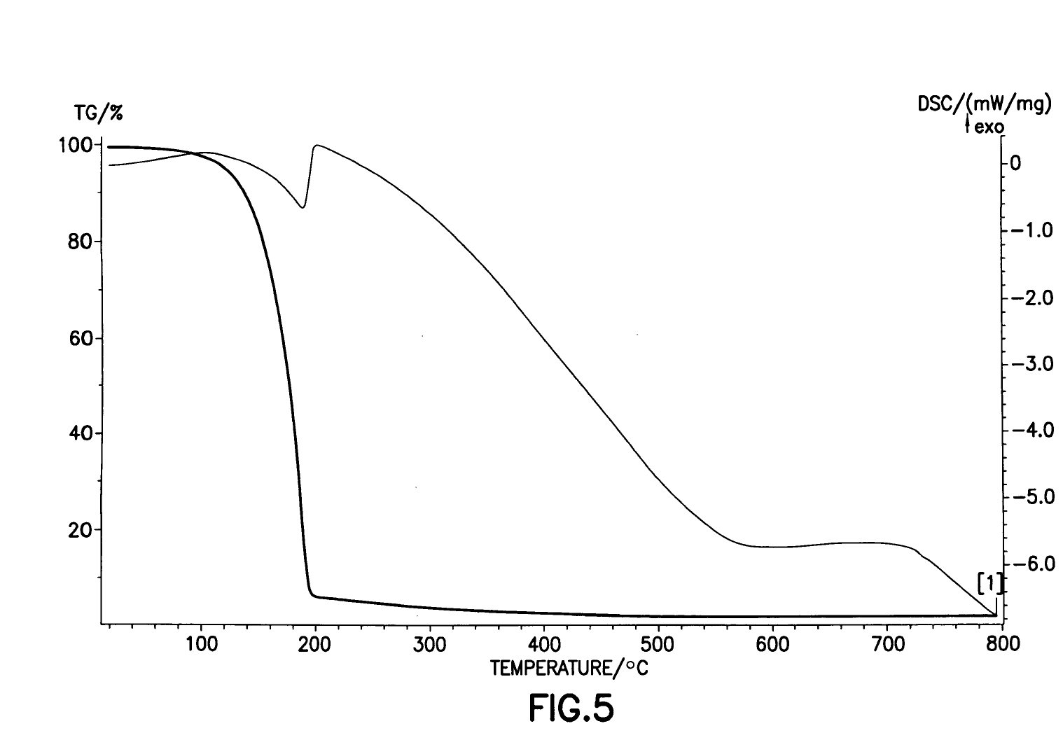

FIG. 5 contains the STA plot for bis(2,2,5,5-tetramethyl-2,5-disila-1-azacyclopentanide)germanium (II), for a 9.99 mg sample, which exhibited a T₅₀ of 177° C. and 1.7% residual mass.

### Example 3

The bis(2,2,5,5-tetramethyl-2,5-disila-1-azacyclopentanide)germanium (II) is reactive with diisopropyl tellurium to form a germanium-silicon-tellurium compound, according to the following reaction:

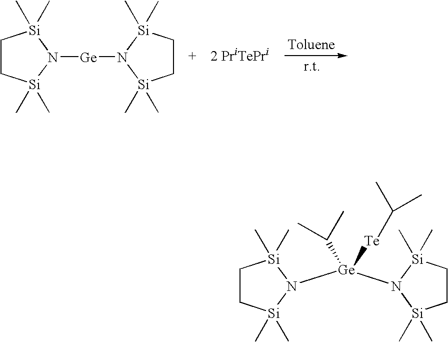

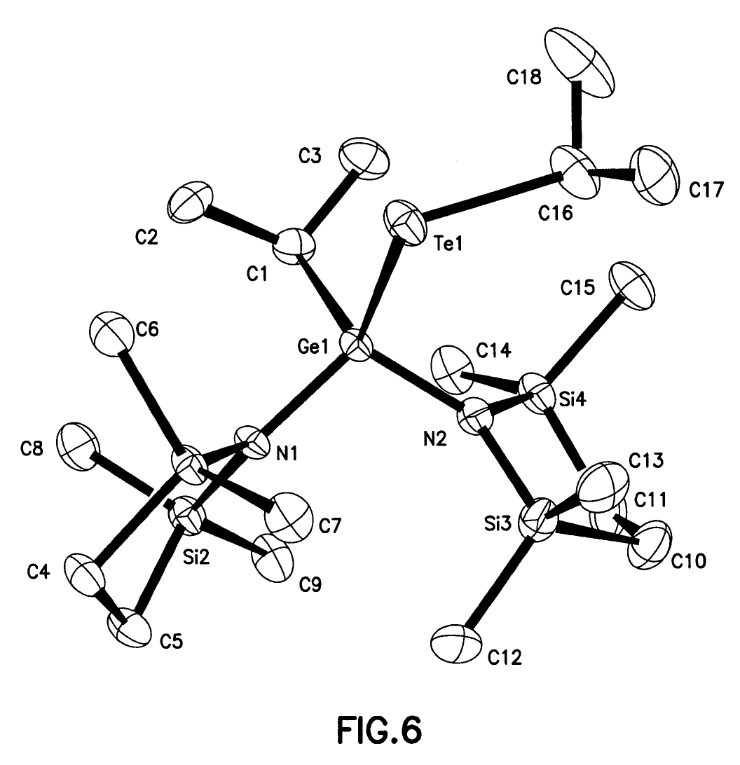

and the ORTEP diagram for this compound is contained in FIG. 6. The Prⁱ(PrⁱTe)GeTMDSACP₂ compound is an off-white solid at room temperature, and is the first known example of a Ge(II) telluro-germane.

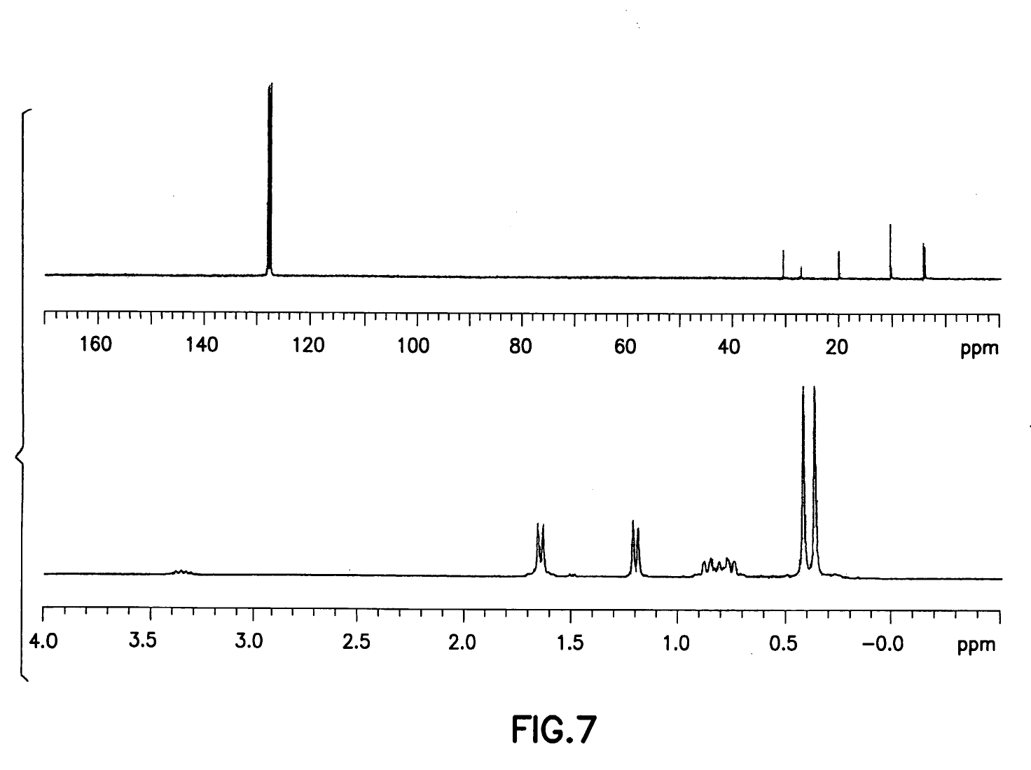

The NMR spectrum for such Ge(II) telluro-germane, Prⁱ(PrⁱTe)GeTMDSACP₂, is shown in FIG. 7.

The calculated and empirically determined component values are set out in Table 4 below.

TABLE 4

| | C (%) | H (%) | N (%) |
|---|---|---|---|
| Calculated | 35.85 | 7.69 | 4.64 |
| Found | 35.87 | 7.82 | 4.66 |

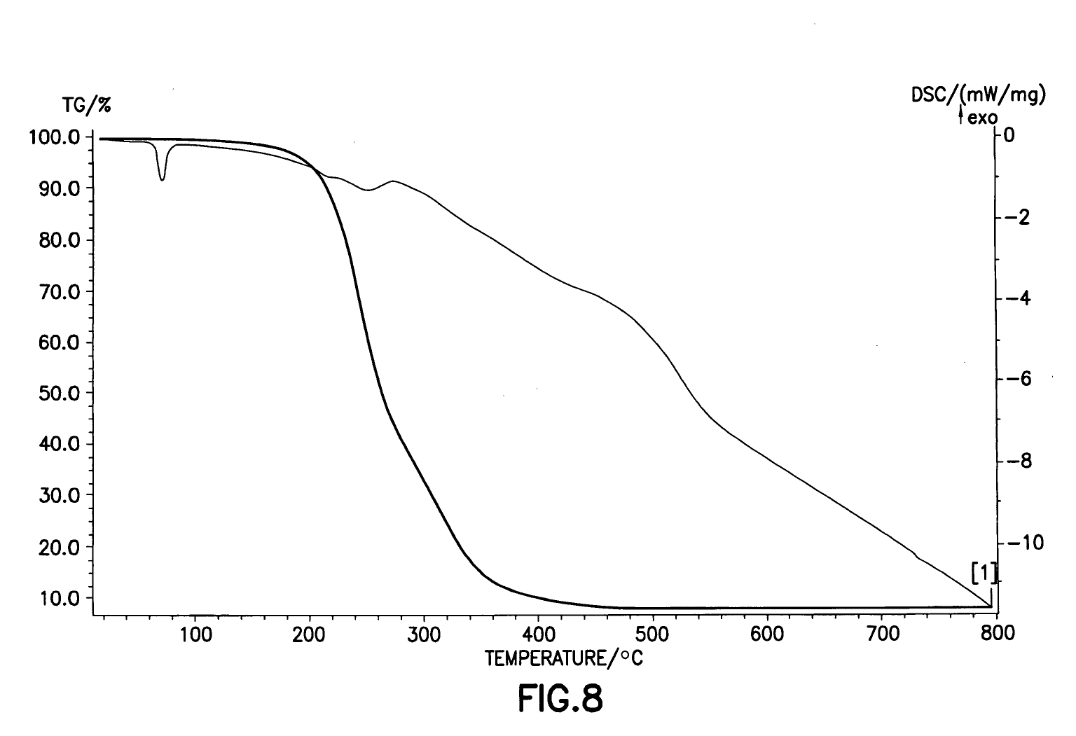

The STA plot for Prⁱ(PrⁱTe)GeTMDSACP₂ is set out in FIG. 8, for a 8.10 mg sample of the compound, which had a T₅₀ at 264° C. and 7.7% mass residual.

### Example 5

The bis(2,2,5,5-tetramethyl-2,5-disila-1-azacyclopentanide)germanium (II) is reactive with diisopropyl carbodimide to form a germanium-guanidinate compound, according to the following reaction:

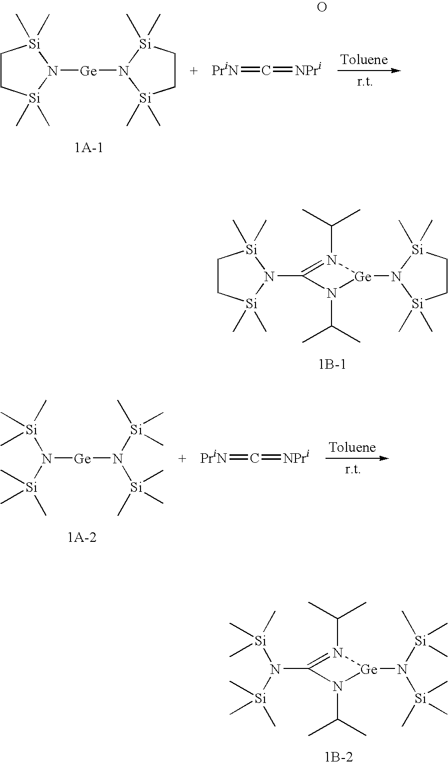

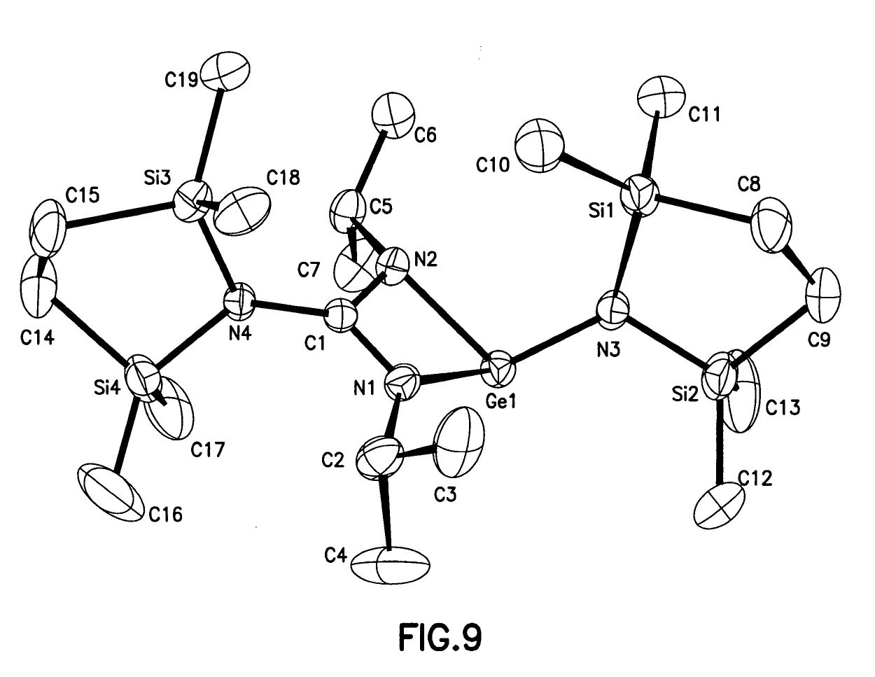

and the ORTEP diagram for 1B-1 compound is contained in FIG. 9.

The Ge(II) guanidinate 1B-1 an off-white solid at room temperature, and is the first known example of a Ge(II) guanidinate.

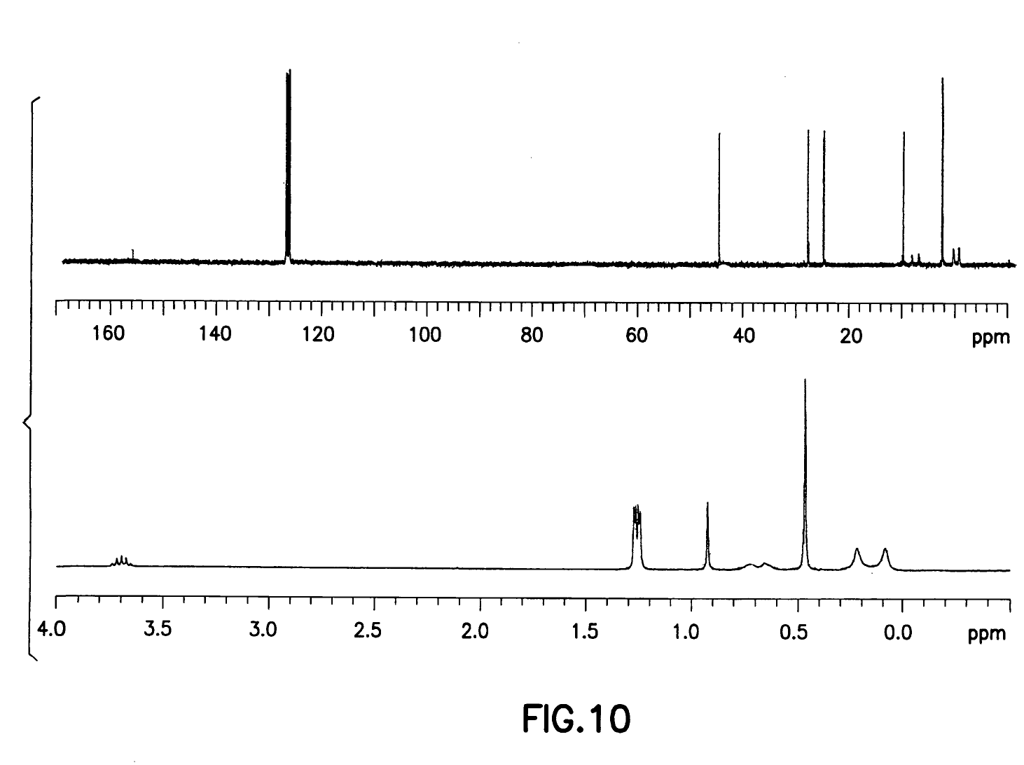

The NMR spectrum for such Ge(II) guanidinate 1B-1 is shown in FIG. 10.

The calculated and empirically determined component values are set out in Table 5 below.

TABLE 5

| 1B-1 | C (%) | H (%) | N (%) |
|---|---|---|---|
| Calculated | 44.26 | 8.99 | 10.87 |
| Found | 44.32 | 9.02 | 10.88 |

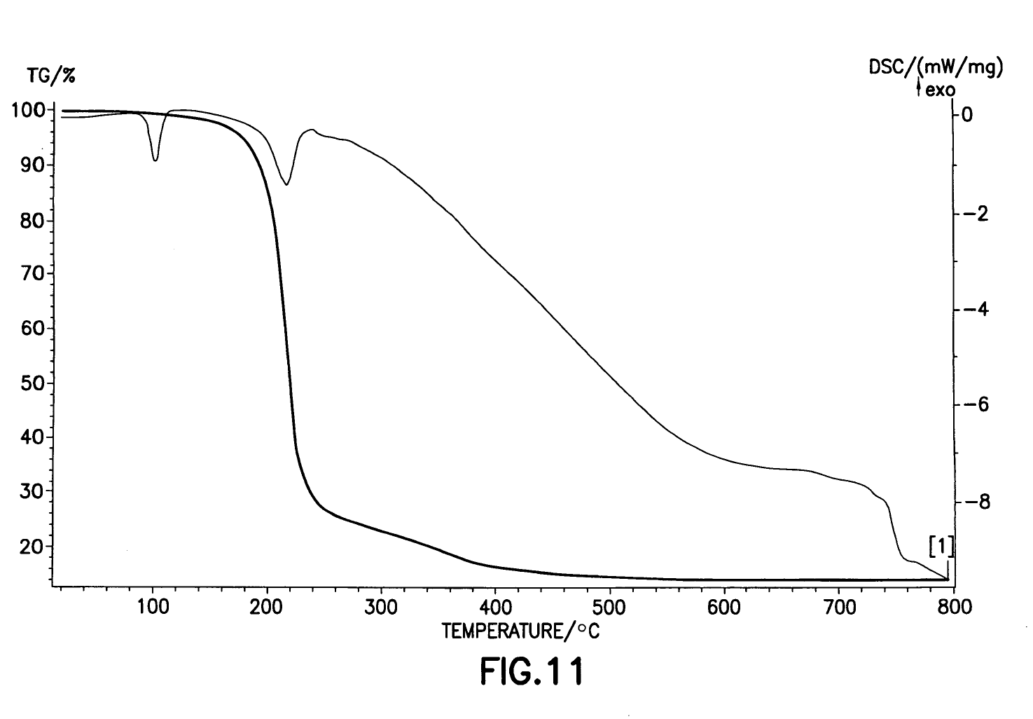

The STA plot for Prⁱ(PrⁱTe)GeTMDSACP₂ is set out in FIG. 11, for a 6.52 mg sample with T50 at 219° C. and 13.8% mass residual.

### Example 6

The tetramethylguanidinate germanium (IV) complexes are synthesized according to the following reaction:

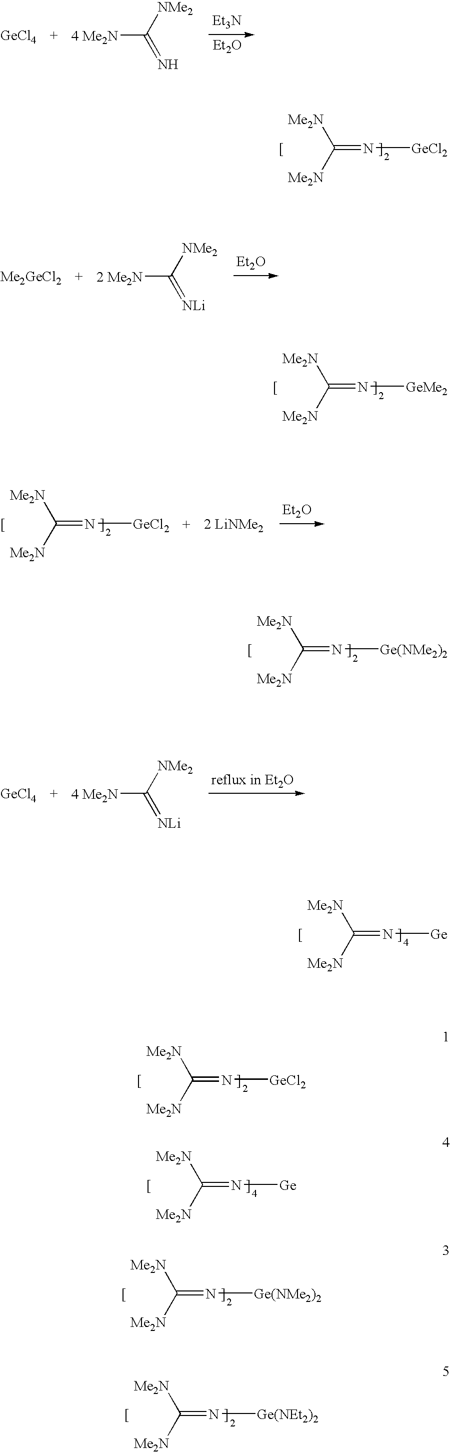

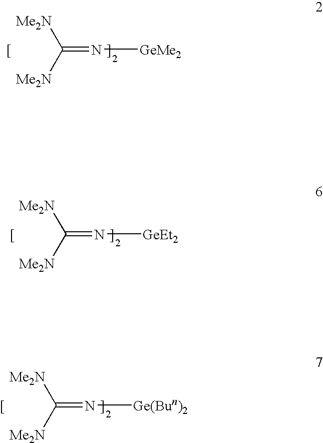

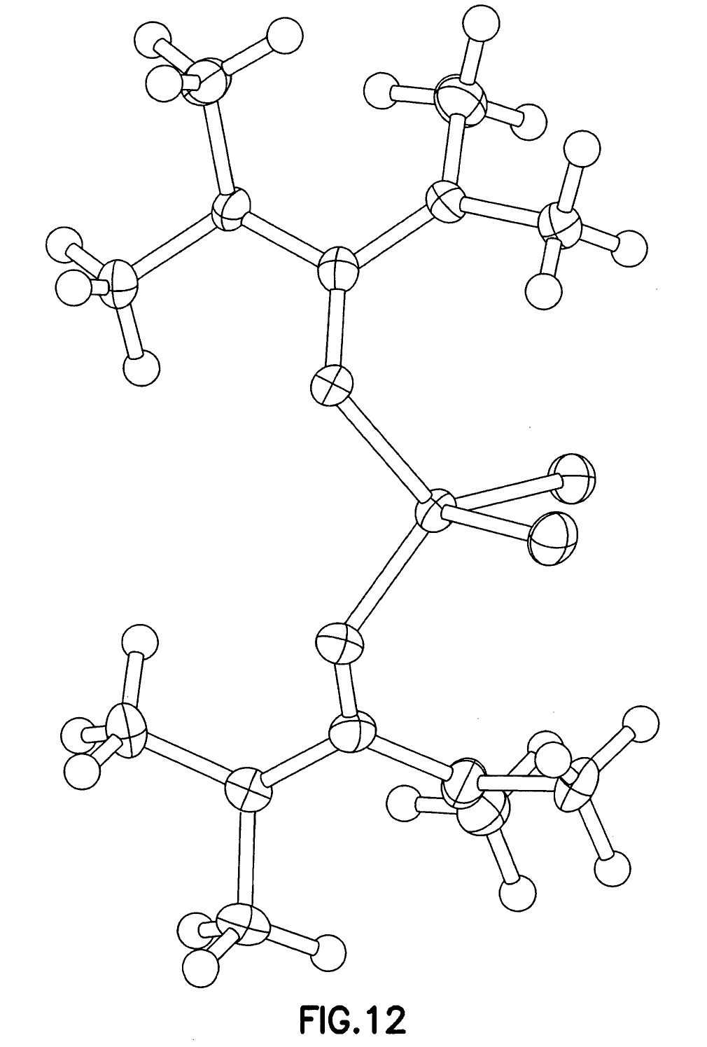

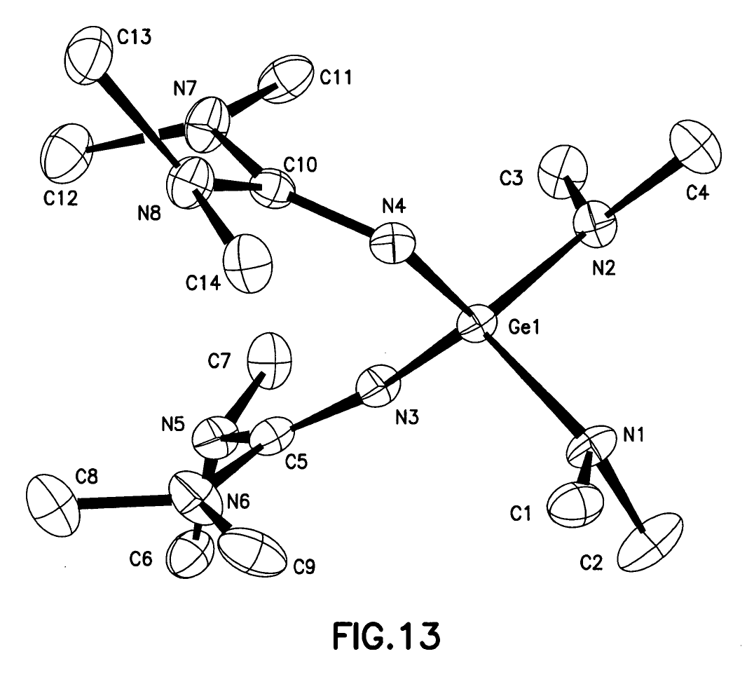

and the ORTEP diagram for TMG₂GeCl₂ (1) and TMG₂Ge(NMe₂)₂ (3) compounds are contained in FIGS. 12 and 13.

Compounds 1, 2, 3 and 4 are off-white solid at room temperature while compounds 5, 6 and 7 are liquids and all of them are the first known example of Ge(IV) guanidinate.

The STA data of compounds 1-6 is summarized in Table 6.

TABLE 6

| Precursor | Melting point (° C.) | T₅₀ (° C.) | Residue (%) |
|---|---|---|---|
| 1 | — | 217 | 3.2 |
| 2 | 57 | 182 | 1.0 |
| 3 | 47 | 207 | 0 |
| 4 | 74 | 255 | 1.1 |
| 5 | ~liquid at R.T. | 221 | 0.41 |
| 6 | ~liquid at R.T. | 199 | 0.44 |
| 7 | ~liquid at R.T. | 218 | 0 |

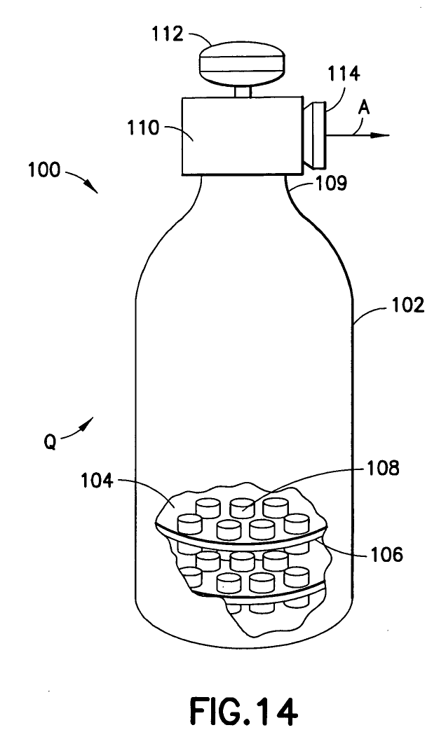

FIG. 14 is a schematic representation of a material storage and dispensing package 100 containing a metal precursor, according to one embodiment of the present invention.

The material storage and dispensing package 100 includes a vessel 102 that may for example be of generally cylindrical shape as illustrated, defining an interior volume 104 therein. In this specific embodiment, the metal precursor is a solid at ambient temperature conditions, and such precursor may be supported on surfaces of the trays 106 disposed in the interior volume 104 of the vessel, with the trays having flow passage conduits 108 associated therewith, for flow of vapor upwardly in the vessel to the valve head assembly, for dispensing in use of the vessel.

The solid precursor can be coated on interior surfaces in the interior volume of the vessel, e.g., on the surfaces of the trays 106 and conduits 108. Such coating may be effected by introduction of the precursor into the vessel in a vapor form from which the solid precursor is condensed in a film on the surfaces in the vessel. Alternatively, the precursor solid may be dissolved or suspended in a solvent medium and deposited on surfaces in the interior volume of the vessel by solvent evaporation. In yet another method the precursor may be melted and poured onto the surfaces in the interior volume of the vessel. For such purpose, the vessel may contain substrate articles or elements that provide additional surface area in the vessel for support of the precursor film thereon.

As a still further alternative, the solid precursor may be provided in granular or finely divided form, which is poured into the vessel to be retained on the top supporting surfaces of the respective trays 106 therein.

The vessel 102 has a neck portion 109 to which is joined the valve head assembly 110. The valve head assembly is equipped with a hand wheel 112 in the embodiment shown. The valve head assembly 110 includes a dispensing port 114, which may be configured for coupling to a fitting or connection element to join flow circuitry to the vessel. Such flow circuitry is schematically represented by arrow A in FIG. 14, and the flow circuitry may be coupled to a downstream ALD or chemical vapor deposition chamber (not shown in FIG. 14).

In use, the vessel 102 is heated, such input of heat being schematically shown by the reference arrow Q, so that solid precursor in the vessel is at least partially volatilized to provide precursor vapor. The precursor vapor is discharged from the vessel through the valve passages in the valve head assembly 110 when the hand wheel 112 is translated to an open valve position, whereupon vapor deriving from the precursor is dispensed into the flow circuitry schematically indicated by arrow A.

In lieu of solid delivery of the precursor, the precursor may be provided in a solvent medium, forming a solution or suspension. Such precursor-containing solvent composition then may be delivered by liquid delivery and flash vaporized to produce a precursor vapor. The precursor vapor is contacted with a substrate under deposition conditions, to deposit the metal on the substrate as a film thereon.

In one embodiment, the precursor is dissolved in an ionic liquid medium, from which precursor vapor is withdrawn from the ionic liquid solution under dispensing conditions.

As a still further alternative, the precursor may be stored in an adsorbed state on a suitable solid-phase physical adsorbent storage medium in the interior volume of the vessel. In use, the precursor vapor is dispensed from the vessel under dispensing conditions involving desorption of the adsorbed precursor from the solid-phase physical adsorbent storage medium.

Supply vessels for precursor delivery may be of widely varying type, and may employ vessels such as those commercially available from ATMI, Inc. (Danbury, Conn.) under the trademarks SDS, SAGE, VAC, VACSorb, and ProE-Vap, as may be appropriate in a given storage and dispensing application for a particular precursor of the invention.

The germanium precursors of the invention thus may be employed to form precursor vapor for contacting with a substrate to deposit a germanium-containing film thereon, with various compositions being usefully adapted for depositing germanium-silicon, germanium-tellurium-silicon, and germanium-tellurium films on such substrates.

The precursors of the invention can be used to conduct chemical vapor deposition or to conduct atomic layer deposition, to yield ALD films of superior conformality that are uniformly coated on the substrate with high step coverage even on high aspect ratio structures.

Accordingly, the precursors of the present invention enable a wide variety of microelectronic devices, e.g., semiconductor products, flat panel displays, etc., to be fabricated with germanium-containing films of superior quality.

The invention in another aspect involves use of control agents to combat vapor phase pre-reaction of the precursors described herein, that otherwise causes uneven nucleation on the substrate, longer incubation times for deposition reactions, and lower quality product films. Such pre-reaction may for example be particularly problematic in applications involving chalcogenide films, related source materials (O, S, Se, Te, Ge, Sb, Bi, etc.), and/or manufacture of phase change memory and thermoelectric devices.

Pre-reaction may occur when the precursor reagents described herein are introduced to the deposition chamber, as in chemical vapor deposition, and may also occur in atomic layer deposition (ALD) processes, depending on the specific arrangement of ALD cycle steps and the specific reagents involved.

The invention therefore contemplates the use of control agents with the precursors described herein, whereby detrimental gas phase pre-reactions are suppressed, mitigated or eliminated, so that deposition reactions are induced/enhanced on the substrate surface, and films of superior character are efficiently formed.

The control agents that can be utilized with precursors of the invention for such purpose include agents selected from the group consisting of (i) heteroatom (O, N, S) organo Lewis base compounds, (ii) free radical inhibitors, and (iii) deuterium-ontaining reagents.

These agents can be utilized to lessen deleterious gas phase pre-reaction I'll precursors by various approaches, including:

(1) addition to the precursor composition of a pre-reaction suppressant comprising one or more heteroatom (O, N, S) organo Lewis base compounds such as 1,4-dioxane, thioxane, ethers, polyethers, triethylamine (TEA), triazine, diamines, N,N,N′,N′-tetramethylethylenediamine, N,N,N′-trimethylethylenediamine, amines, imines, and pyridine;

(2) addition to the precursor composition of a free radical inhibitor, such as butylated hydroxy toluene (BHT), hydroquinone, butylated hydro anisole (BHA), diphenylamine, ethyl vanillin, etc.;

(3) use of modified chalcogenide precursors, in which hydrogen substituents have been replaced with deuterium (D) substituents, to provide deuterated analogs for vapor phase deposition; and

(4) addition to the precursor composition of a deuterium source, to deuterate the precursor in situ.

The pre-reaction-combating agents described above (suppressants, free radical inhibitors, deuterium sources and/or deuterated precursors) can be introduced to any of the feed streams to the vapor deposition process in which the film is to be formed. For example, such pre-reaction-combating agents can be introduced to one or more of precursor feed stream(s), inert carrier gas stream(s) to which chalcogenide precursor(s) or other reagents are subsequently added for flow to the deposition chamber, co-reactant feed stream(s) flowed to the deposition chamber, and/or any other stream(s) that is/are flowed to the deposition chamber and in which the pre-reaction-combating agent(s) is/are useful for reduction or elimination of premature reaction of the precursors that would otherwise occur in the absence of such agent(s).

The aforementioned suppressants, free radical inhibitors and/or deuterium source reagents in specific embodiments are co-injected with the precursor(s), e.g., metal source reagent(s), to effect at least partial reduction of pre-reaction involving the precursor(s) and reagent(s).

The pre-reaction-combating agent can alternatively be added directed to the deposition locus, e.g., the deposition chamber to which the precursor vapor is introduced for contacting with the substrate to deposit the film thereon, to suppress deleterious vapor phase pre-reaction involving the precursor(s) and/or other reagents.

As another approach, in the broad practice of the present invention, the suppressant, free radical inhibitor and/or deuterium source can be added to a solution containing the precursor and/or another metal source reagent, and the resulting solution can be utilized for liquid delivery processing, in which the solution is flowed to a vaporizer to form a source vapor for contacting with the substrate to deposit the deposition species thereon.

Alternatively, if the precursor and/or another metal source reagent are not in an existing solution, the suppressant, free radical inhibitor and/or deuterium source can be added to form a mixture or a solution with the precursor and/or another metal source reagent, depending on the respective phases of the materials involved, and their compatibility/solubility.

As a still further approach, the suppressant, free radical inhibitor and/or deuterium source can be utilized for surface treatment of the substrate prior to contacting of the substrate with the precursor and/or other metal source reagent.

The invention therefore contemplates various vapor deposition compositions and processes for forming films on substrates, in which pre-reaction of the precursors is at least partially attenuated by one or more pre-reaction-combating agents selected from among heteroatom (O, N, S) organo Lewis base compounds, sometimes herein referred to as suppressor agents, free radical inhibitors, and/or deuterium source reagents. Use of previously synthesized deuterated precursors or organometal compounds is also contemplated, as an alternative to in situ deuteration with a deuterium source. By suppressing precursor prereaction with these approaches, product films of superior character can be efficiently formed.

The control agent can be used for combating pre-reaction of chalcogenide precursor in a process in which multiple feed streams are flowed to a deposition locus to form a film on a substrate, wherein at least one of the multiple feed streams includes a precursor susceptible to pre-reaction adversely affecting the film, in which the method involves introducing the control agent to at least one of such multiple feed streams or supplied materials therefor, or to the deposition locus.

The pre-reaction combating reagent alternatively can be introduced to passivate the surface of a growing chalcogenide film or slow the deposition rate, followed by reactivation using an alternative precursor or co-reactant (for example H₂, NH₃, plasma, H₂O, hydrogen sulfide, hydrogen selenide, diorganotellurides, diorganosulfides, diorganoselenides, etc.), thereby carrying out passivation/retardation followed by reactivation steps, e.g., as an alternating repetitive sequence. Such sequence of passivation/retardation followed by reactivation can be carried out for as many repetitive cycles as desired, in ALD or ALD-like processes. The steps may be carried out for the entire deposition operation, or during some initial, intermediate or final portion thereof.

The invention therefore contemplates precursor compositions including the precursor and the pre-reaction-combating reagent. Within the categories of pre-reaction-combating reagents previously described, viz., (i) heteroatom (O, N, S) organo Lewis base compounds, (ii) free radical inhibitors, and (iii) deuterium-containing reagents, suitable pre-reaction-combating reagents for specific applications may be readily determined within the skill of the art, based on the disclosure herein.

Heteroatom (O, N, S) organo Lewis base compounds may be of varied type, e.g., containing an oxo (—O—) moiety, a nitrogen ring atom or pendant amino or amide substituent, a sulfur ring atom or pendant sulfide, sulfonate or thio group, as effective to at least partially lessen pre-reaction of the precursor and other organo metal reagents in the process system. Illustrative examples of heteroatom (O, N, S) organo Lewis base compounds having utility in specific applications of the invention include, without limitation, 1,4-dioxane, thioxane, ethers, polyethers, triethylamine, triazine, diamines, N,N,N′,N′-tetramethylethylenediamine, N,N,N′-trimethylethylenediamine, amines, imines, pyridine, and the like.

The heteroatom organo Lewis base compound in various specific embodiments of the invention may include a guanidinate compound, e.g., (Me₂N)₂C═NH.

One preferred class of heteroatom organo Lewis base compounds for such purpose includes R₃N, R₂NH, RNH₂, R₂N(CH₂)ₙNR₂, R₂NH(CH₂)ₓNR₂, R₂N(CR₂)ₓNR₂, and cyclic amines —N(CH₂)ₓ—, imidazole, thiophene, pyrrole, thiazole, urea, oxazine, pyran, furan, indole, triazole, triazine, thiazoline, oxazole, dithiane, trithiane, crown ethers, 1,4,7-triazacyclononane, 1,5,9-triazacyclododecane, cyclen, succinamide, and substituted derivatives of the foregoing, wherein R can be hydrogen or any suitable organo moieties, e.g., hydrogen, C₁-C₈ alkyl, C₁-C₈ alkoxy, C₁-C₈ alkene, C₁-C₈ alkyne, and C₁-C₈ carboxyl, and wherein x is an integer having a value of from 1 to 6.

The heteroatom organo Lewis base compounds may be utilized in the precursor composition at any suitable concentration, as may be empirically determined by successive deposition runs in which the heteroatom organo Lewis base compound concentration is varied, and character of the resulting film is assessed, to determine an appropriate concentration. In various embodiments, the heteroatom organo Lewis base compound may be utilized in the concentration of 1-300% of the amount of precursor. Specific sub-ranges of concentration values within a range of 0.01-3 equivalents of the heteroatom organo Lewis base compound may be established for specific classes of precursors, without undue experimentation, based on the disclosure herein.

The pre-reaction-combating reagent may additionally or alternatively comprise free radical inhibitors that are effective to lessen the extent of pre-reaction between the precursor and another organo metal reagent. Such free radical inhibitors may be of any suitable type, and may for example include hindered phenols. Illustrative free radical inhibitors include, without limitation, free radical scavengers selected from the group consisting of: 2,6-ditert-butyl-4-methyl phenol, 2,2,6,6-tetramethyl-1-piperidinyloxy, 2,6-dimethylphenol, 2-tert-butyl-4-hydroxyanisole, 3-tert-butyl-4-hydroxyanisole, propyl ester 3,4,5-trihydroxy-benzoic acid, 2-(1,1-dimethylethyl)-1,4 benzenediol, diphenylpicrylhydrazyl, 4-tert-butylcatechol, N-methylaniline, 2,6-dimethylaniline, p-methoxydiphenylamine, diphenylamine, N,N′-diphenyl-p-phenylenediamine, p-hydroxydiphenylamine, phenol, octadecyl-3-(3,5-di-tert-butyl-4-hydroxyphenyl) propionate, tetrakis (methylene (3,5-di-tert-butyl-4-hydroxy-hydrocinnamate) methane, phenothiazines, alkylamidonoisoureas, thiodiethylene bis(3,5,-di-tert-butyl-4-hydroxy-hydrocinnamate, 1,2,-bis (3,5-di-tert-butyl-4-hydroxyhydrocinnamoyl) hydrazine, tris (2-methyl-4-hydroxy-5-tert-butylphenyl) butane, cyclic neopentanetetrayl bis(octadecyl phosphite), 4,4′-thiobis (6-tert-butyl-m-cresol, 2,2′-methylenebis (6-tert-butyl-p-cresol), oxalyl bis(benzylidenehydrazide) and mixtures thereof. Preferred free radical inhibitors include BHT, BHA, diphenylamine, ethyl vanillin, and the like.

Useful concentrations of the free radical inhibitor may be in a range of from 0.001 to about 0.10% by weight of the weight of the precursor, in various specific embodiments. More generally, any suitable amount of free radical inhibitor may be employed that is effective to combat the pre-reaction of the precursor in the delivery and deposition operations involved in the film formation process.

The deuterium source compounds afford another approach to suppressing pre-reaction of the chalcogenide precursor. Such deuterium source compounds may be of any suitable type, and may for example include deuterated pyridine, deuterated pyrimidine, deuterated indole, deuterated imidazole, deuterated amine and amide compounds, deuterated alkyl reagents, etc., as well as deuterated analogs of the precursors that would otherwise be used as containing hydrogen or protonic substituents.

Deuterides that may be useful in the general practice of invention as pre-reaction-combating reagents include, without limitation, germanium and antimony compounds of the formulae RₓGeD₄₋ₓ, and RₓSbD₃₋ₓ wherein R can be hydrogen or any suitable organo moieties, e.g., hydrogen, C₁-C₈ alkyl, C₁-C₈ alkoxy, C₁-C₈ alkene, C₁-C₈ alkyne, and C₁-C₈ carboxyl, and wherein x is an integer having a value of from 1 to 6.

The deuterium source reagent may be utilized at any suitable concentration that is effective to combat pre-reaction of the precursor. Illustrative deuterium source reagent concentrations in specific embodiments of the invention can be in a range of 0.01 to about 5% by weight, based on the weight of precursor.

Thus, a deuterium source compound may be added to one or more of the feed streams to the vapor deposition process, and/or one of the precursors or other feed stream components may be deuterated in the first instance.

The concentrations of the pre-reaction-combating agents utilized in the practice of the present invention to at least partially eliminate pre-reaction of the precursors can be widely varied in the general practice of the present invention, depending on the temperatures, pressures, flow rates and specific compositions involved. The above-described ranges of concentration of the pre-reaction-combating reagents of the invention therefore are to be appreciated as being of an illustrative character only, with applicable concentrations being readily determinable within the skill of the art, based on the disclosure herein.

The specific mode of introduction or addition of the pre-reaction-combating agent to one or more of the feed streams to the deposition process may correspondingly be varied, and may for example employ mass flow controllers, flow control valves, metering injectors, or other flow control or modulating components in the flow circuitry joining the source of the pre-reaction-combating agent with the streams being flowed to the deposition process during normal film-forming operation. The process system may additionally include analyzers, monitors, controllers, instrumentation, etc., as may be necessary or appropriate to a given implementation of the invention.

In lieu of introduction or addition of the pre-reaction-combating agent to one or more of the flow streams to the vapor deposition process, the pre-reaction-combating agent may be mixed with precursor in the first instance, as a starting reagent material for the process. For example, the pre-reaction-combating agent may be mixed in liquid solution with the precursor, for liquid delivery of the resulting precursor solution to a vaporizer employed to generate precursor vapor for contact with the substrate to deposit the film thereon.

As mentioned, the pre-reaction-combating agent may be added to the deposition locus to provide active gas-phase suppression of pre-reaction of the precursor vapor(s) that would otherwise be susceptible to such deleterious interaction.

As a still further alternative, the pre-reaction-combating agent may be used as a preliminary surface treatment following which the precursor and co-reactants (e.g., H₂, NH₃, plasma, H₂O, hydrogen sulfide, hydrogen selenide, diorganotellurides, diorganosulfides, diorganoselenides, etc.) are delivered to the substrate surface to effect deposition on such surface. For such purpose, the pre-reaction-combating agent may be introduced into one of more of the flow lines to the deposition process and flow to the substrate in the deposition process chamber, prior to initiation of flow of any precursors. After the requisite period of contacting of the substrate with such pre-reaction-combating agent has been completed, the flow of the pre-reaction-combating agent can be terminated, and normal feeding of flow streams to the deposition chamber can be initiated.

It will be apparent from the foregoing description that the pre-reaction-combating agent may be introduced in any of a wide variety of ways to effect diminution of the pre-reaction of the precursor in the deposition system.

In one embodiment of the invention, a vapor phase deposition system is contemplated, comprising:

a vapor deposition chamber adapted to hold at least one substrate for deposition of a film thereon;

chemical reagent supply vessels containing reagents for forming the film;

first flow circuitry arranged to deliver said reagents from said chemical reagent supply vessels to the vapor deposition chamber;

a pre-reaction-combating agent supply vessel containing a pre-reaction-combating agent;

second flow circuitry arranged to deliver the pre-reaction-combating agent from the pre-reaction-combating agent supply vessel to the first flow circuitry, to said chemical reagent supply vessels and/or to the vapor deposition chamber.

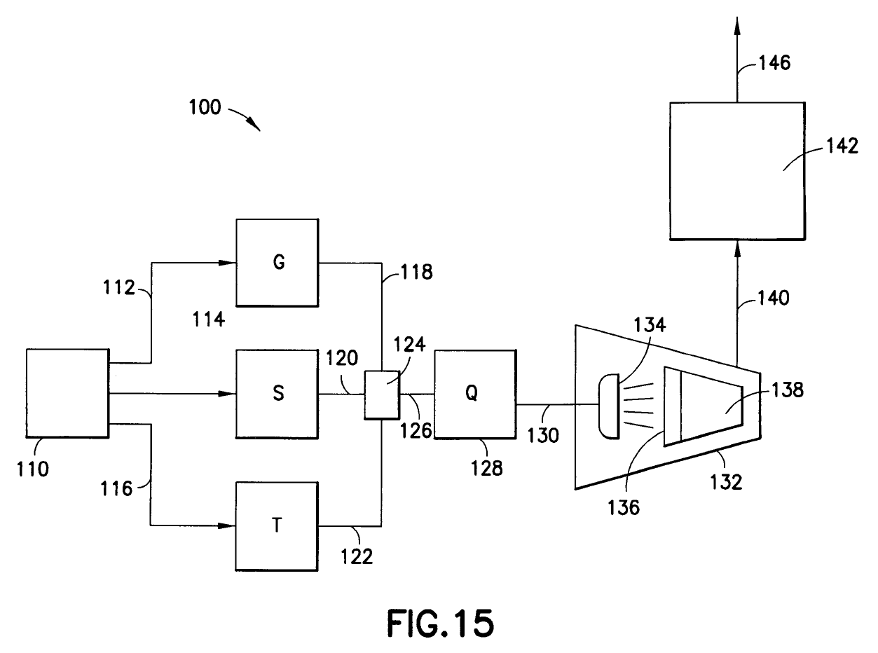

FIG. 15 is a schematic representation of a vapor deposition system 100 in one embodiment thereof.

In this illustrative system, a pre-reaction-combating agent is contained in a supply vessel 110. The pre-reaction-combating agent can comprise a pre-reaction suppressant, a free radical inhibitor, a deuterium source, or a combination of two or more of such agents and/or types of such agents.

The pre-reaction-combating agent supply vessel is joined by respective flow lines 112, 114 and 116, to germanium, antimony and tellurium reagent supply vessels, labeled “G,” “S” and “T,” respectively. The germanium precursor in vessel “G” may be a tetraalkyl or tetraamido germanium compound, such as tetramethyl germanium, tetraethyl germanium, tetraallyl germanium, tetrakis(dimethylamino)germane or other organo germanium compounds. Furthermore, precursor “G” may be a germylene compound wherein the lone pair on Ge(II) can react in the gas-phase with chalcogen precursors in the absence of a pre-reaction suppresant. The antimony precursor in vessel “S” can be a trialkyl or triamido antimony compound, such as tributyl antimony, triisopropyl antimony, tris(dimethylamino)antimony or other organo antimony compound. The tellurium precursor in vessel “T” can be a dialkyl or diamido tellurium compound, such as diisopropyl tellurium, dibutyl tellurium, bis[bis(trimethylsilyl)amino]tellurium or other organo tellurium compound.

The pre-reaction-combating agent therefore can be added to any of the germanium, antimony and/or tellurium precursors in the respective “G,” “S” and “T” vessels, via the corresponding flow line(s), which for such purpose may have flow control valves or other flow-modulating components therein.

In the specific process embodiment shown, the germanium, antimony and tellurium precursors are flowed in liquid form in feed lines 118, 120 and 122, respectively, to the mixing chamber 124, and the resulting precursor mixture then is flowed from the mixing chamber 124 in line 126 to vaporizer 128. In the vaporizer, the liquid precursor mixture and pre-reaction-combating agent are volatilized to form a precursor vapor. The precursor vapor then flows in line 130 to the showerhead disperser 134 in vapor deposition chamber 132, for discharge of precursor mixture onto the wafer substrate 136 mounted on susceptor 138 in the deposition chamber.

The precursor vapor contacting the wafer substrate 136 serves to deposit the germanium, antimony and tellurium metals on the substrate, to form a thin film of germanium-antimony-tellurium (GST) material, e.g., for manufacture of a phase change random access memory device.

The contacted precursor vapor, depleted in metals content, is discharged from the vapor deposition chamber 132 in line 140, and flows to the effluent abatement unit 142. In the effluent abatement unit 142, the discharged effluent vapor is treated, e.g., by scrubbing, catalytic oxidation, electrochemical treatment, or in other manner, to yield a final effluent that is discharged from the abatement unit in line 146.

It will be appreciated that these schematic representation of the vapor deposition system shown in FIG. 15 is of an illustrative character, and that numerous other arrangements could be utilized for deployment and use of the pre-reaction-combating agent, including those previously illustratively discussed herein. For example, the pre-reaction-combating agent could be introduced directly to the mixing chamber 124, for blending therein with the respective GST precursors. Alternatively, the pre-reaction-combating agent could be introduced into manifold 118, or other mixing chamber, blender, etc., for combination with the precursor that is being transported to the deposition locus.

The system shown in FIG. 15 employs liquid delivery of the respective precursors. It will be recognized that if solid-phased precursors are employed, then solid delivery techniques may be employed, in which solid precursor is volatilized, e.g., by sublimation of the solid starting material.

In lieu of using a deuterating agent as the pre-reaction-combating agent in the FIG. 15 system, one or more of the germanium, antimony and tellurium precursors could be supplied in the first instance as a deuterated analog of an organo germanium, antimony or tellurium precursor, in which hydrogen substituents of the organo moiety have been replaced with deuterium.

The pre-reaction-combating reagents may be employed in the broad practice of the present invention to produce improved films for the manufacture of semiconductor products. In general, the pre-reaction-combating reagents described herein may be utilized in various combinations in specific applications, to suppress or eliminate pre-reaction of the precursor and provide superior nucleation and final film properties.

While the invention has been has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. For example, although various precursor compositions are described herein with reference to metal species, it will be appreciated that other corresponding precursors containing metalloid central atoms are contemplated in precursor compositions containing the disclosed coordinating ligands, for deposition of silicon-, metal- and metalloid-containing films (including oxides, nitrides, oxynitrides, carbides, silicides and chalcogenides) on substrates such as microelectronic device wafers and structures. Correspondingly, the invention as hereinafter claimed is intended to be broadly construed and interpreted, as including all such variations, modifications and alternative embodiments, within its spirit and scope.

What is claimed is:

1. A metal precursor selected from the group consisting of:
(a) metal silylamide precursors with one or more disilylazacycloalkyl ligand(s), of the formula 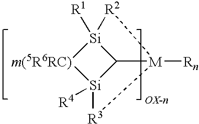
RₙM{N[(R¹R²)Si(CR⁵R⁶)ₘSi(R³R⁴)]}ₒₓ₋ₙ;
(b) metal amides including silylamido ligand(s), of the formula 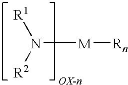
RₙM(N(R¹R²))ₒₓ₋ₙ;
(c) metal amides including silylamido ligand(s), of the formula 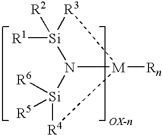
RₙM{[Si(R³R⁴R⁵)NSi(R¹R²R³)]}ₒₓ₋ₙ;
(d) metal precursors including a tetraalkylguanidine ligand, of the formula 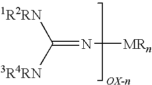
(R)ₙM{N═C[(NR¹R²)(NR³R⁴)]}ₒₓ₋ₙ;
(e) guanidinate complexes of the formula 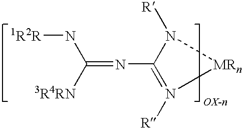
RₙM{R^{.}NC{N═C[(NR¹R²)(NR³R⁴)]}NR^{..}}ₒₓ₋ₙ;
(f) ketimates of the formula 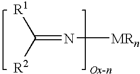
(R)ₙM{N═C(R¹R²)}ₒₓ;
(g) guanidinate complexes of the formula 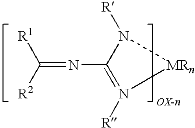
RₙM{(R^{.}NC[N═C(R¹R²)]NR^{..}}ₒₓ₋ₙ;
(h) alkylchalcogenide complexes of the formula 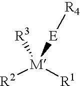
(R¹R²R³)M′(ER⁴);
(i) aminochalcogenide complexes of the formula 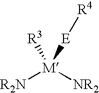
{(NR₂)(NR₂)(R³)}M′(ER⁴); and
(j) dianionic guanidinate complexes of the formula 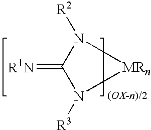
and corresponding complexes comprising singly deprotonated guanidinate ligands;
wherein:
M is a metal or metalloid;
M′ is a Group IV element selected from among C, Si, Ge, Sn and Pb;
OX is the oxidation state of M and M′;
E is a Group VI element selected from among O, S, Se and Te;
n is an integer having a value of from 0 to OX; and
m is an integer having a value of from 0 to 8;
wherein each R (R¹, R², R³, R⁴, R⁵, R⁶, R⁷, R′, R″ and R) is independently selected from among H, C₁-C₆ alkyl, C₃-C₆ cycloalkyl, C₁-C₆ alkoxy, C₁-C₆ fluoroalkyl, amine, aryloxyalkyl, imidoalkyl, acetylalkyl, —NR^{a}R^{b}, C(R^{c})₃, —Si(R⁸)₃, Ge(R⁸)₃ and Cp-C(R^{I}R^{II}R^{III}R^{IV}R^{V}), wherein each of R^{a}, R^{b} and R^{c} is independently selected from C₁-C₆ alkyl; each R⁸ is independently selected from among H, C₁-C₆ alkyl, C₅-C₁₀ cycloalkyl, C₆-C₁₀ aryl, and —Si(R⁹)₃ wherein each R⁹ is independently selected from C₁-C₆ alkyl;
Cp is cyclopentadienyl;
each of cyclopentadienyl substituents R^{I}, R^{II}, R^{III}, R^{IV}, and R^{V} can be the same as or different from the others, and is independently selected from among C₁-C₆ alkyl, C₁-C₆ alkoxy, C₆-C₁₄ aryl, silyl, C₃-C₁₈ alkylsilyl, C₁-C₆ fluoroalkyl, amide, aminoalkyl, alkoxyalkyl, aryloxyalkyl, imidoalkyl, hydrogen and acetylalkyl;
optionally with pendant ligands attached to one or more of said R¹, R², R³, R⁴, R⁵, R⁶, R⁷, R′, R″ and R comprising functional group(s) providing further coordination to the metal center, and selected from among aminoalkyl, alkoxyalkyl, aryloxyalkyl, imidoalkyl, and acetylalkyl, having the following formulae: 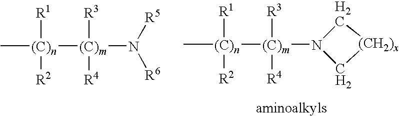
wherein: the methylene (—CH₂—) moiety could alternatively be another divalent hydrocarbyl moiety; each of R₁-R₄ is the same as or different from one another, with each being independently selected from among hydrogen, C₁-C₆ alkyl and C₆-C₁₀ aryl; each of R₅ and R₆ is the same as or different from the other, with each being independently selected from among hydrogen, C₁-C₆ alkyl; n and m are each selected independently as having a value of from 0 to 4, with the proviso that m and n cannot be 0 at the same time, and x is selected from 1 to 5; 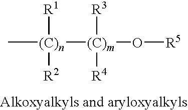
wherein each of R₁-R₄ is the same as or different from one another, with each being independently selected from among hydrogen, C₁-C₆ alkyl, and C₆-C₁₀ aryl; R₅ is selected from among hydrogen, C₁-C₆ alkyl, and C₆-C₁₀ aryl; and n and m are selected independently as having a value of from 0 to 4, with the proviso that m and n cannot be 0 at the same time; 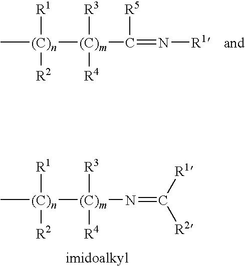
wherein each of R₁, R₂, R₃, R₄, R₅ is the same as or different from one another, with each being independently selected from among hydrogen, C₁-C₆alkyl, and C₆-C₁₀ aryl; each of R₁′, R₂′ is the same as or different from one another, with each being independently selected from hydrogen, C₁-C₆ alkyl, and C₆-C₁₀ aryl; and n and m are selected independently from 0 to 4, with the proviso that m and n cannot be 0 at the same time; 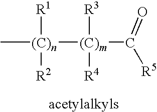
wherein each of R₁-R₄ is the same as or different from one another, with each being independently selected from among hydrogen, C₁-C₆ alkyl, and C₆-C₁₀ aryl; R₅ is selected from among hydrogen, hydroxyl, acetoxy, C₁-C₆ alkyl, C₁-C₁₂ alkylamino, C₆-C₁₀ aryl, and C₁-C₅ alkoxy; and n and m are selected independently from 0 to 4, with the proviso that m and n cannot be 0 at the same time.

2. The metal precursor according to claim 1, comprising a metal precursor (d) including a tetraalkylguanidine ligand, coordinated in a coordination complex of the formula

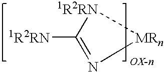

3. The metal precursor according to claim 1, selected from the group consisting of precursors (a), (b) and (c).

4. The metal precursor according to claim 1 (a).

5. The metal precursor according to claim 1 (b).

6. The metal precursor according to claim 1 (c).

7. The metal precursor according to claim 1 (d).

8. The metal precursor according to claim 1 (f).

9. The metal precursor according to claim 1 (h).

10. The metal precursor according to claim 1 (i).

11. The metal precursor according to claim 1 (j).

12. The metal precursor according to claim 1, comprising bis(2,2,5,5-tetramethyl-2,5-disila-1-azacyclopentanide)germanium (II).

13. A method of making bis(2,2,5,5-tetramethyl-2,5-disila-1-azacyclopentanide)germanium (II), comprising:
(a) reacting butyllithium and a disilylamide of the formula: 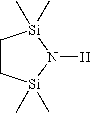
in a solvent medium comprising tetrahydrofuran, to yield a bis(disilylaminolithium)(thf) complex of the formula: 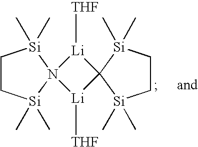
(b) reacting said bis(disilylaminolithium)(thf) complex in the presence of germanium dichloride and dioxane to produce said bis(2,2,5,5-tetramethyl-2,5-disila-1-azacyclopentanide)germanium (II).

14. A method of forming a film on a substrate by chemical vapor deposition or atomic layer deposition, comprising use of a metal precursor of claim 1.

15. The method of claim 14, carried out at temperature <400° C.

16. The method of claim 14, of forming a germanium-containing film on a substrate, said method comprising volatilizing a precursor composition comprising bis(2,2,5,5-tetramethyl-2,5-disila-1-azacyclopentanide)germanium (II), to form a precursor vapor therefrom, and contacting said precursor vapor with the substrate under vapor deposition conditions, to deposit germanium thereon.

17. The method of claim 14, comprising liquid delivery of said metal precursor.

18. The method of claim 17, wherein said metal precursor is dissolved or suspended in a solvent medium.

19. The method of claim 14, comprising solid delivery of the metal precursor.

20. The metal precursor of claim 1, as packaged in a precursor storage and dispensing package.
